(19) United States
(12) Patent Application Publication
(10) Pub. No.: US 2025/0273522 A1
(43) Pub. Date: Aug. 28, 2025

(54) PACKAGE COMPRISING A SUBSTRATE INCLUDING A VIA INTERCONNECT WITH A PARTIAL CONCENTRIC PLANAR CROSS SECTION

(71) Applicant: QUALCOMM Incorporated, San Diego, CA (US)

(72) Inventors: Aniket PATIL, San Diego, CA (US); Joan Rey Villarba BUOT, Escondido, CA (US); Hong Bok WE, San Diego, CA (US)

(21) Appl. No.: 18/589,172

(22) Filed: Feb. 27, 2024

(51) Int. Cl. H01L 23/13; H01L 21/768; H01L 23/00; H01L 23/498; H01L 25/065

(52) U.S. Cl. CPC H01L 23/13; H01L 21/76871; H01L 23/49816; H01L 24/05; H01L 24/13; H01L 25/0655; H01L 2224/05009; H01L 2224/05025; H01L 2224/13009; H01L 2224/13025; H01L 2924/15311; H01L 2924/182

(57) ABSTRACT

A package comprising an integrated device; and a substrate coupled to the integrated device through at least a plurality of solder interconnects. The substrate comprises a plurality of interconnects. The plurality of interconnects comprises a first via interconnect comprising a partial concentric planar cross section; and a second via interconnect comprising a partial ring planar cross section, wherein the second via interconnect laterally surrounds at least part of the first via interconnect.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with substrates and integrated devices.

One example provides a package comprising an integrated device; and a substrate coupled to the integrated device through at least a plurality of solder interconnects. The substrate comprises a plurality of interconnects. The plurality of interconnects comprises a first via interconnect comprising a partial concentric planar cross section; and a second via interconnect comprising a partial ring planar cross section, wherein the second via interconnect laterally surrounds at least part of the first via interconnect.

Another example provides a substrate comprising at least one dielectric layer; and a plurality of interconnects comprising: a first via interconnect comprising a partial concentric planar cross section; and a second via interconnect comprising a partial ring planar cross section, wherein the second via interconnect laterally surrounds at least part of the first via interconnect.

Another example provides a package. The package comprising a first substrate; a first integrated device coupled to the first substrate; a second substrate; an encapsulation layer located between the first substrate and the second substrate, wherein the encapsulation layer is coupled to the first substrate and the second substrate; and a plurality of package interconnects comprising: a first package via interconnect comprising a partial concentric planar cross section; and a second package via interconnect comprising a partial ring planar cross section, wherein the second via interconnect laterally surrounds at least part of the first via interconnect.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes substrates and integrated devices.

FIG. 2 illustrates an exemplary view of a via interconnect with a partial concentric planar cross section.

FIG. 3 illustrates an exemplary view of a via interconnect with a partial concentric planar cross section.

FIG. 4 illustrates an exemplary view of a via interconnect with a partial concentric planar cross section.

FIG. 5 illustrates an exemplary cross sectional plan view of a substrate with a via interconnect with a partial concentric planar cross section.

FIG. 6 illustrates an exemplary cross sectional plan view of a substrate with a via interconnect with a partial concentric planar cross section.

FIG. 7 illustrates an exemplary cross sectional plan view of a substrate panel with a via interconnect with a partial concentric planar cross section.

FIG. 8 illustrates an exemplary cross sectional plan view of a substrate panel cut into individual substrates with a via interconnect with a partial concentric planar cross section.

FIG. 9 illustrates an exemplary cross sectional profile view of a package that includes substrates and integrated devices.

FIG. 10 illustrates an exemplary cross sectional profile view of a package that includes substrates and integrated devices.

FIGS. 11A-11C illustrate an exemplary sequence for fabricating a substrate with a via interconnect with a partial concentric planar cross section.

FIG. 12 illustrates an exemplary flow chart of a method for fabricating a substrate with a via interconnect with a partial concentric planar cross section.

FIGS. 13A-13F illustrate an exemplary sequence for fabricating a package that includes substrates and integrated devices.

FIG. 14 illustrates an exemplary flow chart of a method for fabricating a package that includes substrates and integrated devices.

FIGS. 15A-15B illustrate an exemplary sequence for fabricating a substrate.

FIG. 16 illustrates an exemplary flow chart of a method for fabricating a substrate.

FIG. 17 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure a package comprising an integrated device; and a substrate coupled to the integrated device through at least a plurality of solder interconnects. The substrate comprises a plurality of interconnects. The plurality of interconnects comprises a first via interconnect comprising a partial concentric planar cross section; and a second via interconnect comprising a partial ring planar cross section, wherein the second via interconnect laterally surrounds at least part of the first via interconnect. The use of the first via interconnect and the second via interconnect help provide more interconnects in the substrate, which can help improve the performance of the package.

Exemplary Package Comprising a Substrate with Partial Coaxial Interconnect Structures

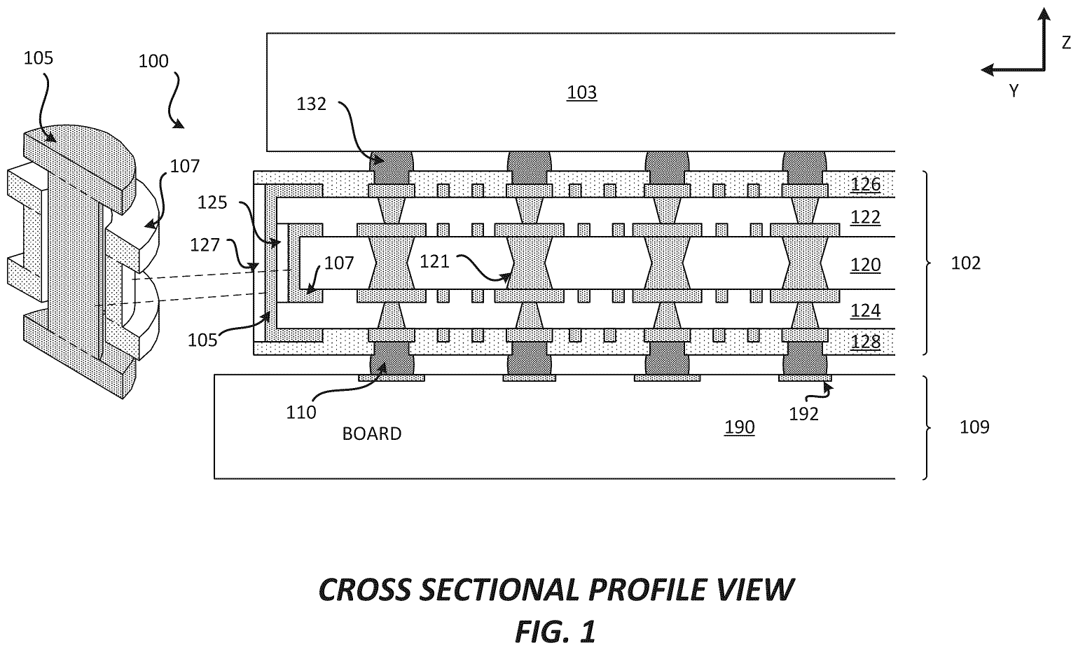

FIG. 1 illustrates a cross sectional profile view of a package 100 that includes partial coaxial interconnect structures. The package 100 may be implemented as part of a package on package (PoP). The package 100 is coupled to a board 109 through a plurality of solder interconnects 110. The board 109 includes at least one board dielectric layer 190 and a plurality of board interconnects 192. The board 109 may include a printed circuit board (PCB).

The package 100 includes a substrate 102 and an integrated device 103. The integrated device 103 is coupled to the substrate 102 through at least a plurality of solder interconnects 132. For example, the integrated device 103 is coupled to a plurality of interconnects 121 of the substrate 102 through at least a plurality of solder interconnects 132. The substrate 102 includes a core layer 120, a dielectric layer 122, a dielectric layer 124, a plug dielectric layer 125, a plug dielectric layer 127, a plurality of interconnects 121, a solder resist layer 126 and a solder resist layer 128. The core layer 120 may include a dielectric. The core layer 120 may include a different dielectric from the dielectric layer 122 and/or the dielectric layer 124. The core layer 120 may include a same dielectric from the dielectric layer 122 and/or the dielectric layer 124. The dielectric layer 122 and/or the dielectric layer 124 may include prepreg. The plug dielectric layer 127 may include the same material as the dielectric layer 122 and/or the dielectric layer 124. The plug dielectric layer 127 may include a different material from the dielectric layer 122 and/or the dielectric layer 124. The plug dielectric layer 127 may include a plug material.

The plurality of interconnects 121 may include a partial concentric interconnect structure 105 and a partial concentric interconnect structure 107. The partial concentric interconnect structure 107 may include a partial ring interconnect structure. The partial concentric interconnect structure 105 may include a partial ring interconnect structure. As will be further described below, the partial concentric interconnect structure 105 and the partial concentric interconnect structure 107 may be configured as a partial coaxial interconnect structure.

The partial concentric interconnect structure 105 may extend through the dielectric layer 122, the core layer 120 and the dielectric layer 124. At least part of the partial concentric interconnect structure 105 may be located in and/or (i) the surface of the dielectric layer 122 and/or (ii) the surface of the dielectric layer 124. The partial concentric interconnect structure 107 may extend through at least the core layer 120. The plug dielectric layer 125 may be located laterally between the partial concentric interconnect structure 105 and the partial concentric interconnect structure 107. At least part of the partial concentric interconnect structure 107 may be located in (i) the dielectric layer 122 and/or (ii) the dielectric layer 124. The partial concentric interconnect structure 105 and/or the partial concentric interconnect structure 107 may be located near and/or along an edge of the substrate 102. The partial concentric interconnect structure 107 may laterally surround at least part of the partial concentric interconnect structure 105. The plug dielectric layer 127 may be coupled to and touch at least part of the partial concentric interconnect structure 105 and/or at least part of the partial concentric interconnect structure 107. The plug dielectric layer 127 may be located along one or more edges of the substrate 102. The plug dielectric layer 127 may represent an outer side wall of the substrate 102. The plug dielectric layer 127 may be similar to the plug dielectric layer 125.

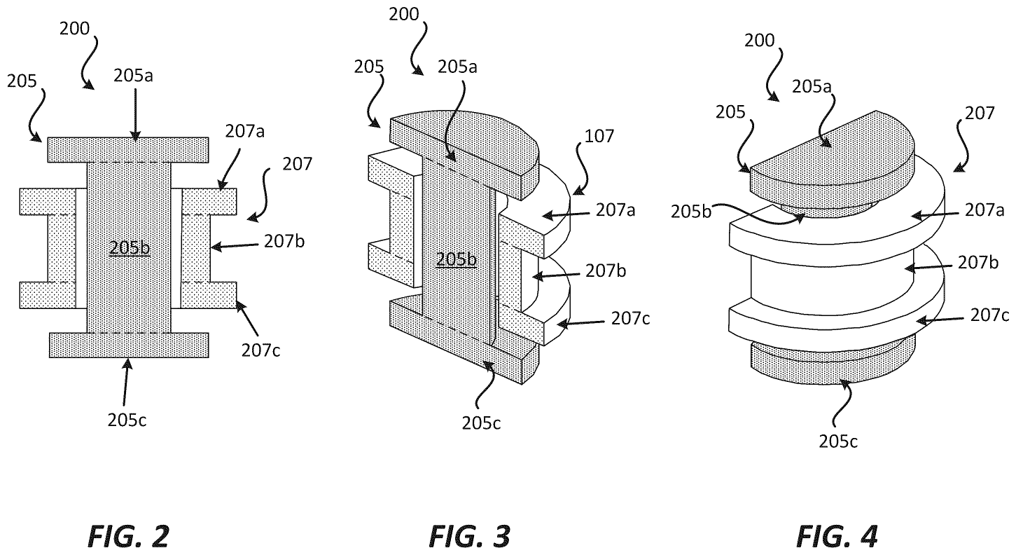

The partial concentric interconnect structure 105 may include a first pad interconnect, a first via interconnect and a second pad interconnect. As will be further illustrated and described below in at least FIGS. 2-4, the first pad interconnect may have a partial concentric cross section, the first via interconnect may have a partial concentric cross section, and the second pad interconnect may have a partial concentric cross section (e.g., a partial ring cross section).

The partial concentric interconnect structure 107 may include a third pad interconnect, a second via interconnect and a fourth pad interconnect. The partial concentric interconnect structure 107 may include a partial ring interconnect structure. As will be further illustrated and described below in at least FIGS. 2-4, the third pad interconnect may have a partial ring cross section, the second via interconnect may have a partial ring cross section, and the fourth pad interconnect may have a partial ring cross section.

In some implementations, the partial concentric interconnect structure 107 may help provide shielding (e.g., provide electromagnetic interference shield) for a current traveling through the partial concentric interconnect structure 105.

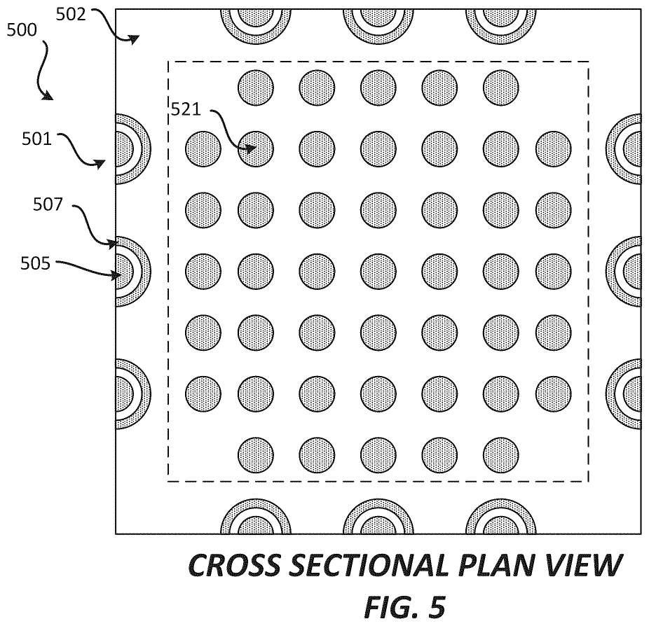

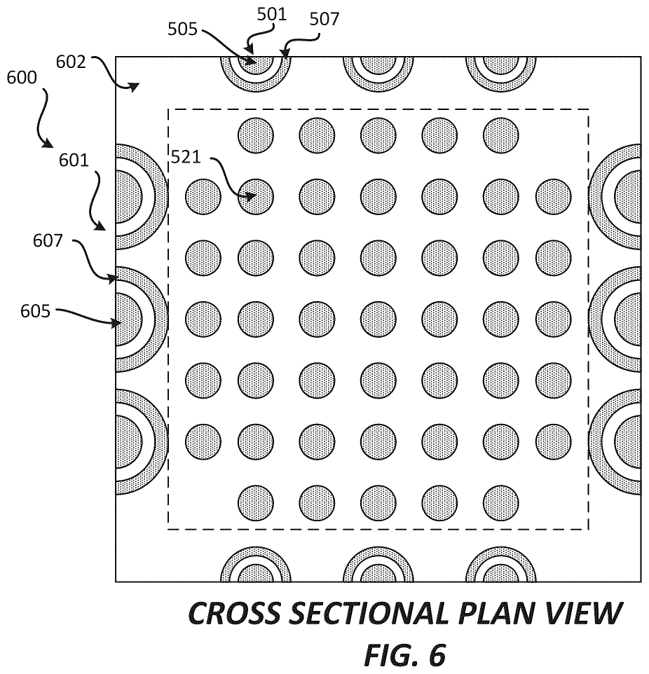

As will be further illustrated and described below in at least FIGS. 5 and 6, the substrate 102 may include a plurality of partial concentric interconnect structures (e.g., 105) and/or a plurality of partial concentric interconnect structures (e.g., 107) that are located along one or more edges of the substrate 102. The substrate 102 may include a plurality of partial concentric interconnect structures (e.g., 105) and/or a plurality of partial concentric interconnect structures (e.g., 107) that are located at least partially within one or more edge regions of the substrate 102. A plurality of partial concentric interconnect structures (e.g., 107) may include a plurality of partial ring interconnect structures.

The combination of the partial concentric interconnect structure 105 and the partial concentric interconnect structure 107 may form and/or define a partial coaxial interconnect structure configured to provide two electrical paths. The partial concentric interconnect structure 105 may be configured to provide a first electrical path. The partial concentric interconnect structure 107 may be configured to provide a second electrical path. In some implementations, the partial concentric interconnect structure 105 may be configured to provide a first electrical path for signal or power, and the partial concentric interconnect structure 107 may be configured to provide a second electrical path for ground. In some implementations, the partial concentric interconnect structure 105 may be configured to provide a first electrical path for ground, and the partial concentric interconnect structure 107 may be configured to provide a second electrical path for signal or power.

A first electrical path between the integrated device 103 and the board 109 may include (i) a solder interconnect from the plurality of solder interconnects 132, (ii) at least one interconnect from the plurality of interconnects 121, (iii) the partial concentric interconnect structure 105, (iv) at least one interconnect from the plurality of interconnects 121, (v) a solder interconnect from the plurality of solder interconnects 110, and/or (vi) a board interconnect from the plurality of board interconnects 192.

A second electrical path between the integrated device 103 and the board 109 may include (i) a solder interconnect from the plurality of solder interconnects 132, (ii) at least one interconnect from the plurality of interconnects 121, (iii) the partial concentric interconnect structure 107, (iv) at least one interconnect from the plurality of interconnects 121, (v) a solder interconnect from the plurality of solder interconnects 110, and/or (vi) a board interconnect from the plurality of board interconnects 192.

The use of the partial concentric interconnect structure 105 and the partial concentric interconnect structure 107 located along one or more edges of the substrate 102 helps provide more electrical paths to and from the integrated device 103, which helps improve the performance of the integrated device 103 and/or the package 100. One, forming the partial concentric interconnect structure 105 and the partial concentric interconnect structure 107 along the edge of the substrate 102 utilizes a region that would have been previously unused, helps increase the number of electrical paths without necessarily increasing the size of the substrate 102 and/or the package 100. Two, the design of the partial concentric interconnect structure 105 and the partial concentric interconnect structure 107 helps provide interconnects that have smaller pitches and/or are closer to each other, which increases the density (e.g., increases the number of interconnects) for a given size. Three, forming the partial concentric interconnect structure 105 and the partial concentric interconnect structure 107, such that the partial concentric interconnect structure 107 laterally surrounds at least part of the partial concentric interconnect structure 105 helps provide shielding of current and/or signals traveling through the partial concentric interconnect structure 105, which can help improve the performance of the integrated device 103 and/or the package 100. Thus, the partial concentric interconnect structure 105 and the partial concentric interconnect structure 107 help provide improved performance of the power distribution network of the package 100 and/or improved impedance of the package 100.

As mentioned above, the partial concentric interconnect structure 105 (e.g., first partial concentric interconnect structure) and the partial concentric interconnect structure 107 (e.g., second partial concentric interconnect structure) may be located along one or more edges of the substrate 102. In some implementations, the partial concentric interconnect structure 105 and the partial concentric interconnect structure 107 may be located at least partially in an edge region of the substrate 102. In some implementations, an edge region of the substrate 102 may be defined as a region of the substrate 102 that is within about 100 micrometers of an edge of the substrate 102. For example, in some implementations, an edge region of the substrate 102 be a region that is within 100 micrometers of the outer surface of the plug dielectric layer 127. It is noted that different implementations may have define an edge region differently. In some implementations, a partial concentric interconnect structure that is located along one or more edges of the substrate 102 may mean a partial concentric interconnect structure that is located at least partially in the edge region of the substrate 102. Thus, in at least some implementations, a partial concentric interconnect structure that is located at least partially in an edge region of the substrate 102 may be considered to be located along an edge of the substrate 102.

FIGS. 2-4 illustrate exemplary views of a partial coaxial interconnect structure 200. The partial coaxial interconnect structure 200 is configured to provide a first electrical path and a second electrical path. The partial coaxial interconnect structure 200 includes a partial concentric interconnect structure 205 and a partial concentric interconnect structure 207. The partial concentric interconnect structure 205 may be configured to provide a first electrical path. The partial concentric interconnect structure 205 may represent the partial concentric interconnect structure 105. The partial concentric interconnect structure 207 may be configured to provide a second electrical path. The partial concentric interconnect structure 207 may represent the partial concentric interconnect structure 107.

The partial concentric interconnect structure 205 includes a first pad interconnect 205a, a first via interconnect 205b and a second pad interconnect 205c. The first pad interconnect 205a is coupled to the first via interconnect 205b. The second pad interconnect 205c is coupled to the first via interconnect 205b. The first pad interconnect 205a includes a partial concentric planar cross section (e.g., semi concentric planar cross section, partial oval planar cross section, partial circular planar cross section, partial ring planar cross section). The first via interconnect 205b includes a partial concentric planar cross section (e.g., semi concentric planar cross section, partial oval planar cross section, partial circular planar cross section, partial ring planar cross section). The second pad interconnect 205c includes a partial concentric planar cross section (e.g., semi concentric planar cross section, partial oval planar cross section, partial circular planar cross section, partial ring planar cross section). The first pad interconnect 205a may be coupled to an interconnect from the plurality of interconnects 121. The second pad interconnect 205c may be coupled to an interconnect from the plurality of interconnects 121.

The partial concentric interconnect structure 207 includes a third pad interconnect 207a, a second via interconnect 207b and a fourth pad interconnect 207c. The third pad interconnect 207a is coupled to the second via interconnect 207b. The fourth pad interconnect 207c is coupled to the second via interconnect 207b. The third pad interconnect 207a includes a partial concentric planar cross section (e.g., partial ring planar cross section). The second via interconnect 207b includes a partial concentric planar cross section (e.g., partial ring planar cross section). The fourth pad interconnect 207c includes a partial concentric planar cross section (e.g., partial ring planar cross section). The third pad interconnect 207a may be coupled to an interconnect from the plurality of interconnects 121. The fourth pad interconnect 207c may be coupled to an interconnect from the plurality of interconnects 121.

The partial concentric interconnect structure 207 laterally surrounds at least part of the partial concentric interconnect structure 205. As shown in FIGS. 2-4, the partial concentric interconnect structure 207 may laterally surround at least part of the first via interconnect 205b of the partial concentric interconnect structure 205. The second via interconnect 207b may laterally surround at least part of the first via interconnect 205b. The third pad interconnect 207a may laterally surround at least part of the first via interconnect 205b. The fourth pad interconnect 207c may laterally surround at least part of the first via interconnect 205b.

In some implementations, the partial concentric interconnect structure 207 may help provide shielding (e.g., provide electromagnetic interference shield) for a current traveling through the partial concentric interconnect structure 205.

In some implementations, a plug dielectric layer (e.g., 125) may be located laterally between the partial concentric interconnect structure 205 and the partial concentric interconnect structure 207. For example, a plug dielectric layer may be located laterally between (i) the first via interconnect 205b of the partial concentric interconnect structure 205 and (ii) the third pad interconnect 207a, the second via interconnect 207b and the fourth pad interconnect 207c of the partial concentric interconnect structure 207.

FIG. 5 illustrates an exemplary plan view of a substrate 500. The substrate 500 may be a representation of the substrate 102. The substrate 500 includes an edge region 502. The substrate 500 also includes a plurality of interconnects 521 and a plurality of partial coaxial interconnect structures 501. The plurality of interconnects 521 may represent the plurality of interconnects 121. A partial coaxial interconnect structure from the plurality of partial coaxial interconnect structures 501 may include a partial concentric interconnect structure 505 and a partial concentric interconnect structure 507. The partial concentric interconnect structure 505 may be the partial concentric interconnect structure 105. The partial concentric interconnect structure 507 may be the partial concentric interconnect structure 107. The plurality of partial coaxial interconnect structures 501 may be located in the edge region 502 of the substrate 500. In some implementations, the edge region 502 may be a region that is located within 100 micrometers of one or more edges of the substrate 500. Different implementations may define the edge region 502 differently.

FIG. 6 illustrates an exemplary plan view of a substrate 600. The substrate 600 may be a representation of the substrate 102. FIG. 6 illustrates that a partial coaxial interconnect structure may have different sizes and/or different shapes. The substrate 600 includes an edge region 602. The substrate 600 also includes a plurality of interconnects 521, a plurality of partial coaxial interconnect structures 501 and a plurality of partial coaxial interconnect structures 601. A partial coaxial interconnect structure from the plurality of partial coaxial interconnect structures 601 may be laterally bigger than a partial coaxial interconnect structure from the plurality of partial coaxial interconnect structures 501. The plurality of interconnects 521 may represent the plurality of interconnects 121. A partial coaxial interconnect structure from the plurality of partial coaxial interconnect structures 601 may include a partial concentric interconnect structure 605 and a partial concentric interconnect structure 607. The partial concentric interconnect structure 605 may be the partial concentric interconnect structure 105. The partial concentric interconnect structure 607 may be the partial concentric interconnect structure 107. The plurality of partial coaxial interconnect structures 501 and the plurality of partial coaxial interconnect structures 601 may be located in the edge region 602 of the substrate 600. In some implementations, the edge region 602 may be a region that is located within 100 micrometers of one or more edges of the substrate 600. Different implementations may define the edge region 602 differently.

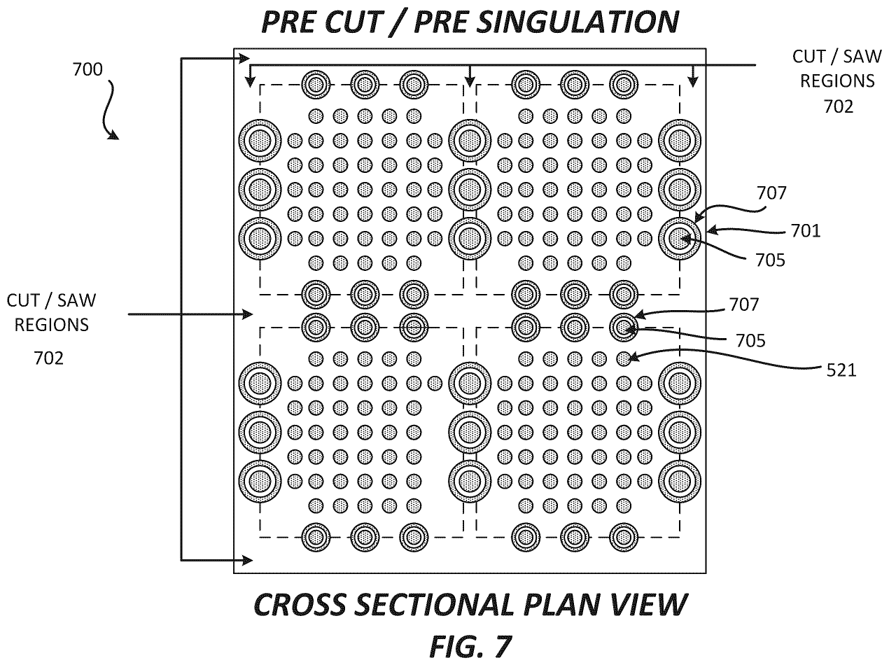

FIG. 7 illustrates an exemplary plan view of a panel 700 (e.g., substrate panel) that includes a plurality of interconnects 521 and a plurality of coaxial interconnect structures 701. FIG. 7 may illustrate the panel 700 before singulation into individual substrates. The panel 700 include cut regions 702. The panel 700 may include a substrate or a panel (e.g., substrate panel) of continuous and/or contiguous substrates. Each coaxial interconnect structure from the plurality of coaxial interconnect structures 701 may include a concentric interconnect structure 705 and a concentric interconnect structure 707. The concentric interconnect structure 705 may be similar to the partial concentric interconnect structure 105, except that the concentric interconnect structure 705 may have a concentric planar cross section. The concentric interconnect structure 707 may be similar to the partial concentric interconnect structure 107, except that the concentric interconnect structure 707 may have a ring planar cross section. The plurality of coaxial interconnect structures 701 may have coaxial interconnect structures with different sizes and/or different shapes. As shown in FIG. 7, the plurality of coaxial interconnect structures 701 are located at least partially in the cut regions 702 of the panel 700. The cut regions of the panel 700 are regions where a blade may travel through when cutting and/or singulating the panel 700.

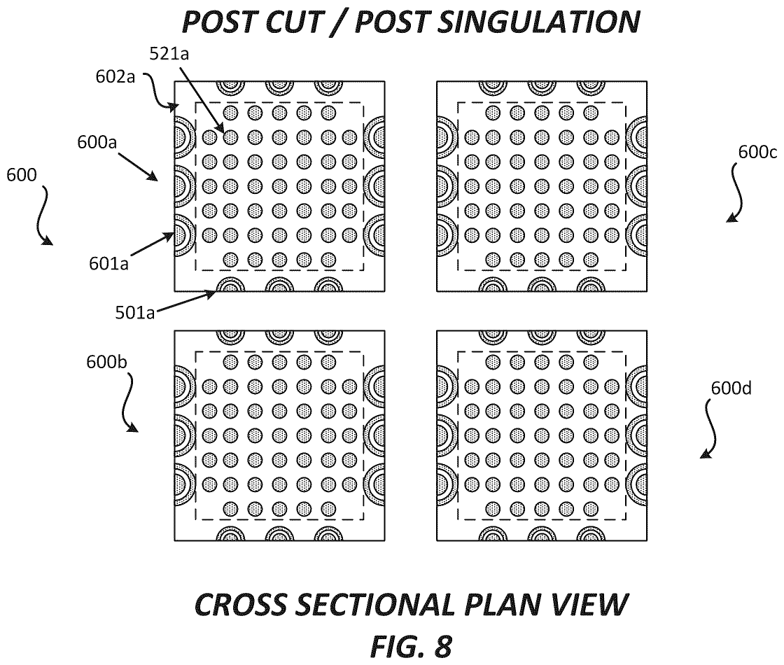

FIG. 8 illustrates an example plan view of the panel 700 (e.g., substrate panel) after singulation into a plurality of substrates (e.g., 600). The panel 700 may be cut (e.g., using a saw) along the cut regions of the panel 700 to form the substrate 600a, the substrate 600b, the substrate 600c and the substrate 600d. Each of the substrates may include a plurality of partial coaxial interconnect structures. For example, the substrate 600a may include an edge region 602a, a plurality of interconnects 521a, a plurality of partial coaxial interconnect structures 501a and a plurality of partial coaxial interconnect structures 601a. The plurality of partial coaxial interconnect structures 501a and the plurality of partial coaxial interconnect structures 601a may be formed from the plurality of coaxial interconnect structures 701 after cutting the panel 700 along the cut regions 702. The plurality of partial coaxial interconnect structures 501a and the plurality of partial coaxial interconnect structures 601a are located at least partially in the edge region 602a of the substrate 600a.

The disclosure illustrates and describes the plurality of partial coaxial interconnect structures to be located in a cored substrate. However, any of the plurality of partial coaxial interconnect structures (e.g., 201, 501, 601) and/or any of partial concentric interconnect structures (e.g., 105, 107, 505, 507, 605, 607) may be implemented in any type of substrate (e.g., laminated substrate, coreless substrate, embedded trace substrate).

Moreover, in some implementations, portions of the partial coaxial interconnect structure may be exposed on the side. For example, in some implementations, it is possible that during the cut of the panel, portions of the plug dielectric layer 127 may be removed to the point that portions of the partial coaxial interconnect structure are exposed and may represent part of the side wall of the substrate. In some implementations, there may not be a plug dielectric layer 127 on the side wall or side surface of the substrate after singulation. Thus, in some implementations, the package 100 and/or the substrate 102 of FIG. 1 may not include the plug dielectric layer 127 or may include a plug dielectric layer 127 that only partially covers the partial concentric interconnect structure 105 and/or the partial concentric interconnect structure 107.

### Exemplary Package Comprising Package Partial Coaxial Interconnect Structures

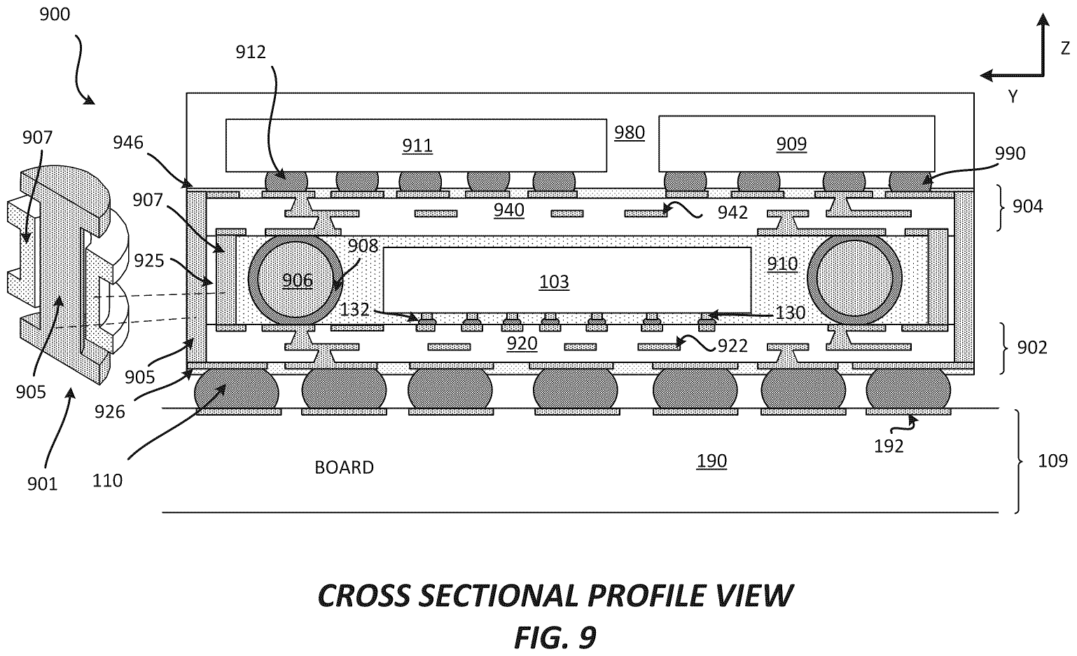

FIG. 9 illustrates a cross sectional profile view of a package 900 that includes package partial coaxial interconnect structures. The package 900 may be implemented as part of a package on package (POP). The package 900 is coupled to a board 109 through a plurality of solder interconnects 110. The board 109 includes at least one board dielectric layer 190 and a plurality of board interconnects 192. The board 109 may include a printed circuit board (PCB).

The package 900 includes a substrate 902, a substrate 904, an integrated device 103, an integrated device 909, an integrated device 911, an encapsulation layer 910, an encapsulation layer 980, a plurality of package balls 906, a plurality of solder interconnects 908 and a package partial coaxial interconnect structure 901. The package partial coaxial interconnect structure 901 may include a partial concentric interconnect structure 905 and a partial concentric interconnect structure 907.

The substrate 902 includes at least one dielectric layer 920 and a plurality of interconnects 922. The substrate 902 may be a first substrate. The substrate 904 includes at least one dielectric layer 940 and a plurality of interconnects 942. The substrate 902 may be a second substrate. The integrated device 103 is coupled to the substrate 902 through a plurality of pillar interconnects 130 and a plurality of solder interconnects 132. The substrate 904 is coupled to the substrate 902 through the plurality of package balls 906 and the plurality of solder interconnects 908. The plurality of package balls 906 and the plurality of solder interconnects 908 may be coupled to the plurality of interconnects 922 of the substrate 902 and the plurality of interconnects 942 of the substrate 904. The encapsulation layer 910, the integrated device 103, the plurality of package balls 906 and the plurality of solder interconnects 908 are located between the substrate 902 and the substrate 904. The encapsulation layer 910 may at least partially encapsulate the integrated device 103. The encapsulation layer 910 may be coupled to the substrate 902 and the substrate 904. The substrate 902 and/or the substrate 904 may include a laminated substrate. The substrate 904 may include an interposer.

The integrated device 911 is coupled to a top surface of the substrate 904 through a plurality of solder interconnects 912. The integrated device 909 is coupled to a top surface of the substrate 904 through a plurality of solder interconnects 990. The encapsulation layer 980 is coupled to a top surface of the substrate 904. The encapsulation layer 980 may at least partially encapsulate the integrated device 911 and the integrated device 909. The substrate 902 is coupled to the board 109 through the plurality of solder interconnects 110.

The package partial coaxial interconnect structure 901 is formed and located at least in the substrate 902, the encapsulation layer 910 and the substrate 904. The package partial coaxial interconnect structure 901 may be located along an edge region of the package 900, an edge region of the substrate 902, an edge region of the encapsulation layer 910 and/or an edge region of the substrate 904.

In some implementations, an edge region of the package 900 may be defined as a region of the package 900 that is within about 100 micrometers of one or more edges of the package 900. In some implementations, an edge region of the substrate 902 may be defined as a region of the substrate 902 that is within about 100 micrometers of one or more edges of the substrate 902. In some implementations, an edge region of the substrate 904 may be defined as a region of the substrate 904 that is within about 100 micrometers of one or more edges of the substrate 904. In some implementations, an edge region of the encapsulation layer 910 may be defined as a region of the encapsulation layer 910 that is within about 100 micrometers of one or more edges of the encapsulation layer 910. A package partial coaxial interconnect structure that is located along an edge of a component may mean that the package partial coaxial interconnect structure is located at least partially in the edge region of the component.

As mentioned above, the package partial coaxial interconnect structure 901 includes a partial concentric interconnect structure 905 and a partial concentric interconnect structure 907. The partial concentric interconnect structure 905 extends through the substrate 902, the encapsulation layer 910 and the substrate 904. The partial concentric interconnect structure 907 extends through at least the encapsulation layer 910. The partial concentric interconnect structure 907 may be located at least partially in the substrate 902, the encapsulation layer 910 and the substrate 904. The package 900 may include a plurality of package partial coaxial interconnect structures that are located along one or more edges of the package. The package 900 may include a plurality of package partial coaxial interconnect structures that are located at least partially within one or more edge regions of the package.

The partial concentric interconnect structure 905 may be configured in a similar manner as the partial concentric interconnect structure 205 of FIGS. 2-4. Thus, the partial concentric interconnect structure 205 may represent the partial concentric interconnect structure 905. The partial concentric interconnect structure 907 may be configured in a similar manner as the partial concentric interconnect structure 207 of FIGS. 2-4. Thus, the partial concentric interconnect structure 207 may represent the partial concentric interconnect structure 907. The shapes, sizes and/or components of the partial concentric interconnect structure 205 and/or the partial concentric interconnect structure 207 may be applicable to the partial concentric interconnect structure 905 and/or the partial concentric interconnect structure 907.

The partial concentric interconnect structure 905 may include a first package pad interconnect that is part of the substrate 904. The partial concentric interconnect structure 905 may include a first package via interconnect that extends through the substrate 904, the encapsulation layer 910 and the substrate 902. The partial concentric interconnect structure 905 may include a second package pad interconnect that is part of the substrate 902.

The partial concentric interconnect structure 907 may include a third package pad interconnect that is part of the substrate 904. The partial concentric interconnect structure 907 may include a first package via interconnect that extends through the encapsulation layer 910. The partial concentric interconnect structure 907 may include a fourth package pad interconnect that is part of the substrate 902. The third package pad interconnect of the partial concentric interconnect structure 907 may be located on a different metal layer of the substrate 904 from the first package pad interconnect of the partial concentric interconnect structure 905. The fourth package pad interconnect of the partial concentric interconnect structure 907 may be located on a different metal layer of the substrate 902 from the second package pad interconnect of the partial concentric interconnect structure 905.

The partial concentric interconnect structure 907 may laterally surround at least part of the partial concentric interconnect structure 905. For example, the package via interconnect of the partial concentric interconnect structure 907 may laterally surround at least part of the package via interconnect of the partial concentric interconnect structure 905. A plug dielectric layer 925 may be located laterally between the partial concentric interconnect structure 905 and the partial concentric interconnect structure 907. The plug dielectric layer 925 may include a material that is different and/or similar to the encapsulation layer 910. It is noted that at least part of the partial concentric interconnect structure 905 and/or at least part of the partial concentric interconnect structure 907 may be exposed and be part of the side wall and/or side surface of the package 900.

The partial concentric interconnect structure 905 may be configured to provide a first electrical path. The partial concentric interconnect structure 907 may be configured to provide a second electrical path. In some implementations, the partial concentric interconnect structure 905 may be configured to provide an electrical path for signal or power, and the partial concentric interconnect structure 907 may be configured to provide an electrical path for ground. In some implementations, the partial concentric interconnect structure 905 may be configured to provide an electrical path for ground, and the partial concentric interconnect structure 907 may be configured to provide an electrical path for signal or power.

A first electrical path between the integrated device 911 and the board 109 may include (i) a solder interconnect from the plurality of solder interconnects 912, (ii) at least one interconnect from the plurality of interconnects 942, (iii) the partial concentric interconnect structure 905, (iv) at least one interconnect from the plurality of interconnects 922, (v) a solder interconnect from the plurality of solder interconnects 110 and/or (vi) a board interconnect from the plurality of board interconnects 192.

A second electrical path between the integrated device 911 and the board 109 may include (i) a solder interconnect from the plurality of solder interconnects 912, (ii) at least one interconnect from the plurality of interconnects 942, (iii) the partial concentric interconnect structure 907, (iv) at least one interconnect from the plurality of interconnects 922, (v) a solder interconnect from the plurality of solder interconnects 110 and/or (vi) a board interconnect from the plurality of board interconnects 192.

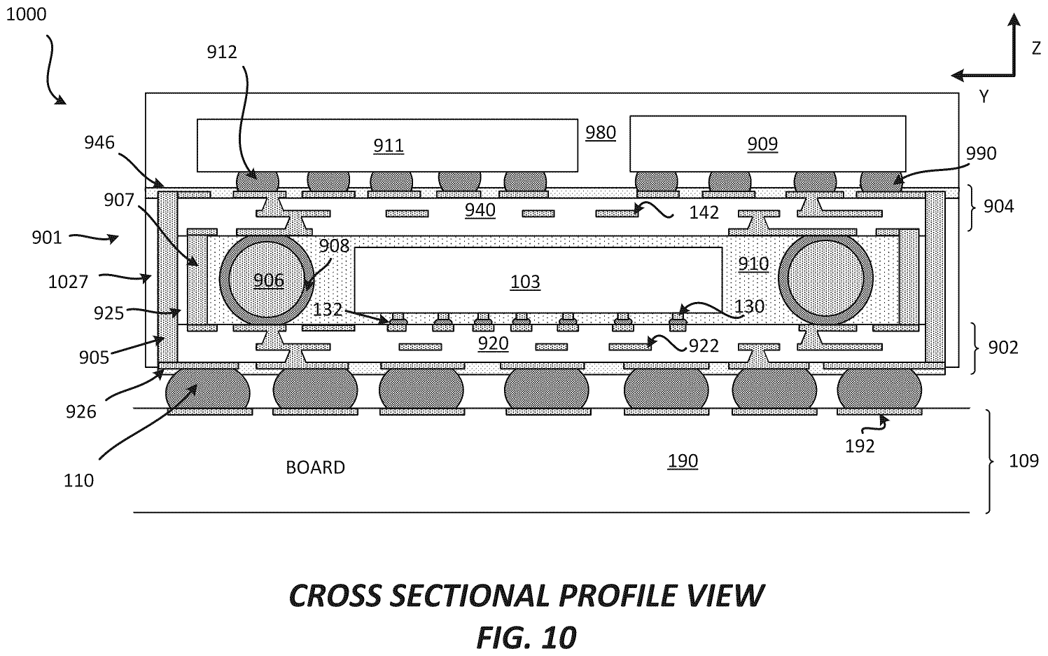

FIG. 10 illustrates a cross sectional profile view of a package 1000 that includes package partial coaxial interconnect structures. The package 1000 is similar to the package 900 and may include similar components that are arranged in a similar manner as the package 900. Thus, the description of the package 900 may be applicable to the package 1000.

The package 1000 includes a substrate 902, a substrate 904, an integrated device 103, an integrated device 909, an integrated device 911, an encapsulation layer 910, an encapsulation layer 980, a plurality of package balls 906, a plurality of solder interconnects 908, a package partial coaxial interconnect structure 901 and a plug dielectric layer 1027. The package partial coaxial interconnect structure 901 may include a partial concentric interconnect structure 905 and a partial concentric interconnect structure 907.

The plug dielectric layer 1027 may include material that is similar and/or different from the plug dielectric layer 925 and/or the encapsulation layer 910. The plug dielectric layer 1027 may be coupled to the partial concentric interconnect structure 905 and/or the partial concentric interconnect structure 907. The plug dielectric layer 1027 may be a side wall and/or side surface of the package 1000. The plug dielectric layer 1027 may cover at least part of the partial concentric interconnect structure 905 and/or the partial concentric interconnect structure 907 so that the partial concentric interconnect structure 905 and/or the partial concentric interconnect structure 907 are not exposed.

An integrated device (e.g., 103, 909, 911) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc., . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 900, 1000) may be implemented in a radio frequency (RF) package. The RF package may be a radio frequency front end (RFFE) package. A package (e.g., 100, 900, 1000) may be configured to provide Wireless Fidelity (WiFi) communication and/or cellular communication (e.g., 2G, 3G, 4G, 5G). The packages (e.g., 100, 900, 1000) may be configured to support Global System for Mobile (GSM) Communications, Universal Mobile Telecommunications System (UMTS), and/or Long-Term Evolution (LTE). The packages (e.g., 100, 900, 1000) may be configured to transmit and receive signals having different frequencies and/or communication protocols.

### Exemplary Sequence for Fabricating a Substrate

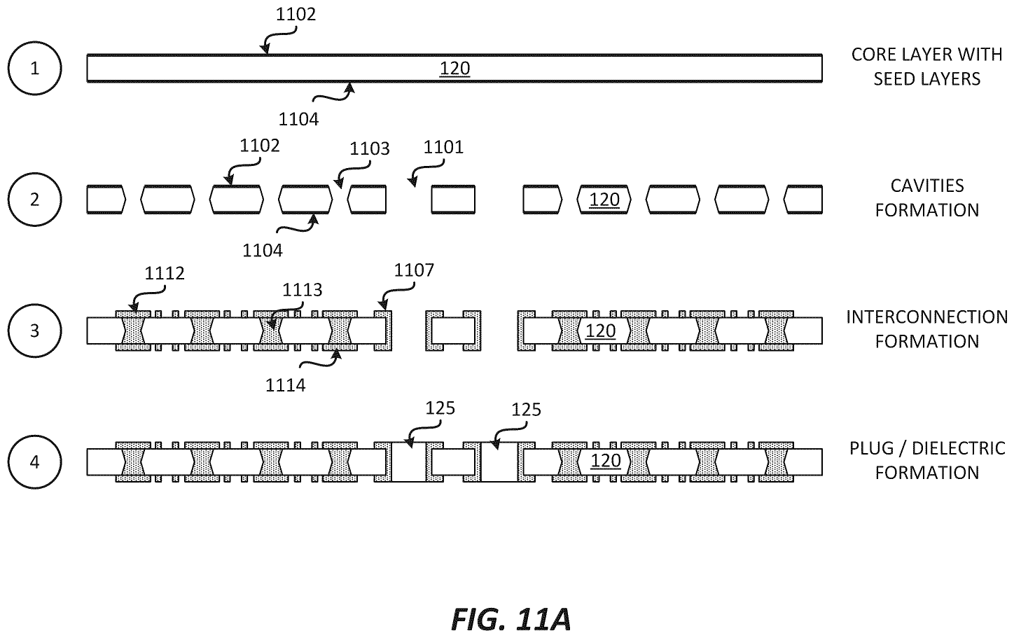

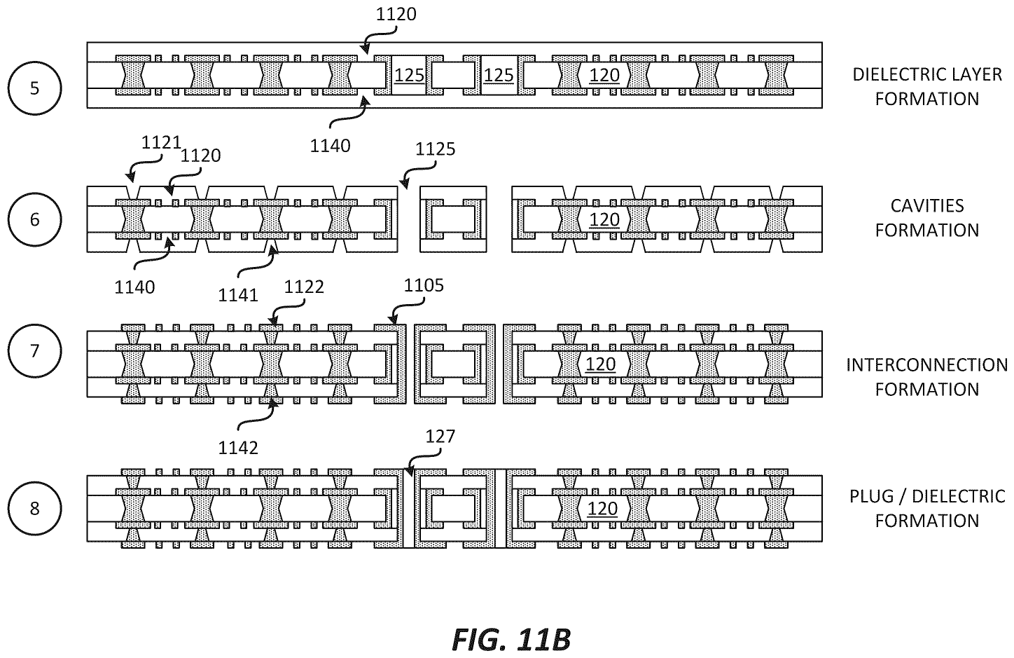

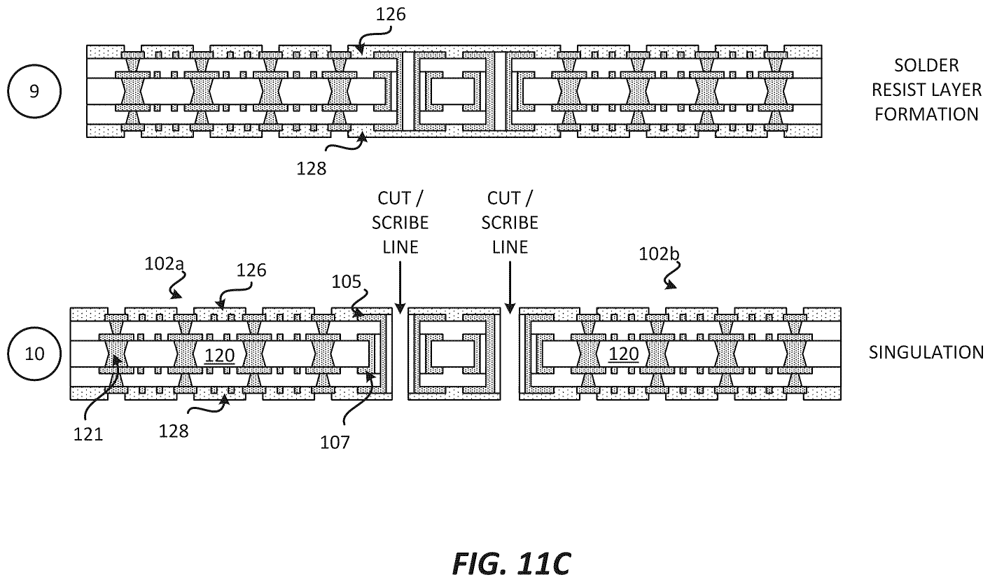

In some implementations, fabricating a substrate includes several processes. FIGS. 11A-11C illustrate an exemplary sequence for providing or fabricating a substrate. In some implementations, the sequence of FIGS. 11A-11C may be used to provide or fabricate the substrate 102. However, the process of FIGS. 11A-11C may be used to fabricate any of the substrates described in the disclosure.

It should be noted that the sequence of FIGS. 11A-11C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 11A, illustrates a state after a core layer 120 is provided. A seed layer 1102 and a seed layer 1104 may be coupled to surfaces of the core layer 120. The core layer 120 may include a dielectric. The seed layer 1102 and/or the seed layer 1104 may include copper (Cu).

Stage 2 illustrates a state after a the plurality of cavities 1101 and a plurality of cavities 1103 are formed and extend through the seed layer 1102, the core layer 120 and the seed layer 1104. A laser ablation process may be used to form the plurality of cavities 1101 and/or the plurality of cavities 1103.

Stage 3 illustrates a state after a plurality of interconnects 1112, a plurality of interconnects 1113, a plurality of interconnects 1114 and a plurality of interconnects 1107 are formed. A lithography process, a plating process, a strip process and/or an etching process may be used to form the plurality of interconnects 1112, the plurality of interconnects 1113, the plurality of interconnects 1114 and the plurality of interconnects 1107. The plurality of interconnects 1112 may include interconnects formed on a first surface of the core layer 120 and/or seed layer 1102. The plurality of interconnects 1113 may include interconnects formed in the core layer 120. The plurality of interconnects 1114 may include interconnects formed on a second surface of the core layer 120 and/or seed layer 1104. As will be further described below, the plurality of interconnects 1107 may become a plurality of partial concentric interconnect structures (e.g., 107) for a substrate.

Stage 4 illustrates a state after a plug dielectric layer 125 is formed in the plurality of cavities 1101. The plug dielectric layer 125 may include a mold, a resin and/or an epoxy. Different implementations may use different dielectric materials for the plug dielectric layer 125. The plug dielectric layer 125 may be coupled to the plurality of interconnects 1107.

Stage 5, as shown in FIG. 11B, illustrates a state after dielectric layer 1120 and the dielectric layer 1140 are formed. The dielectric layer 1120 are formed the plurality of interconnects 1112. The dielectric layer 1140 are formed over the plurality of interconnects 1114. A deposition and/or lamination process may be used to form the dielectric layer 1120 and/or the dielectric layer 1140. The dielectric layer 1120 and/or the dielectric layer 1140 may include prepreg and/or polyimide.

Stage 6 illustrates a state after a plurality of cavities 1125, a plurality of cavities 1121 and a plurality of cavities 1141 are formed. The plurality of cavities 1125 may extend through the dielectric layer 1120, the plug dielectric layer 125 and the dielectric layer 1140. A laser ablation process may be used to form the plurality of cavities 1125. The plurality of cavities 1121 may be formed in the dielectric layer 1120. The plurality of cavities 1141 may be formed in the dielectric layer 1140. An exposure process and a development process may be used to form the plurality of cavities 1121 and the plurality of cavities 1141.

Stage 7 illustrates a state after a plurality of interconnects 1122, a plurality of interconnects 1124 and a plurality of interconnects 1105 are formed. A lithography process, a plating process, a strip process and/or an etching process may be used to form the plurality of interconnects 1122, the plurality of interconnects 1124 and the plurality of interconnects 1105. The plurality of interconnects 1122 may include interconnects formed on a surface of the dielectric layer 1120. The plurality of interconnects 1124 may include interconnects formed on a surface of the dielectric layer 1140. As will be further described below, the plurality of interconnects 1105 may become a plurality of partial concentric interconnect structures (e.g., 105) for a substrate.

Stage 8 illustrates a state after a plug dielectric layer 127 is formed in the plurality of cavities 1125. The plug dielectric layer 127 may include a mold, a resin and/or an epoxy. Different implementations may use different dielectric materials for the plug dielectric layer 127. The plug dielectric layer 127 may be coupled to the plurality of interconnects 1105.

Stage 9, as shown in FIG. 11B, illustrates a state after a solder resist layer 126 and a solder resist layer 128 are formed. A deposition process and/or lamination process may be used to form the solder resist layer 126 and/or the solder resist layer 128. The solder resist layer 126 and/or the solder resist layer 128 may include openings. An etching process, an exposure process and/or a development process may be used to form the openings in the solder resist layer 126 and/or the openings in the solder resist layer 128.

Stage 10 illustrates a state after a singulation process that cut a panel (e.g., substrate panel) into individual substrates (e.g., 102a, 102b). The substrate 102a includes a plurality of partial concentric interconnect structures 105 and a plurality of partial concentric interconnect structures 107. The plurality of partial concentric interconnect structures 105 may be formed through the cutting along a cut line that includes the plurality of interconnects 1105. The plurality of partial concentric interconnect structures 107 may be formed through the cutting along a cut line that includes the plurality of interconnects 1107. The substrate 102a may include the core layer 120, a plurality of dielectric layers (e.g., 1120, 1140), a plurality of interconnects 121, a plurality of partial concentric interconnect structures 105 and a plurality of partial concentric interconnect structures 107, a solder resist layer 126 and a solder resist layer 128. The plurality of interconnects 121 may represent a plurality of interconnects 1112, a plurality of interconnects 1113, a plurality of interconnects 1114, a plurality of interconnects 1122 and/or a plurality of interconnects 1142.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

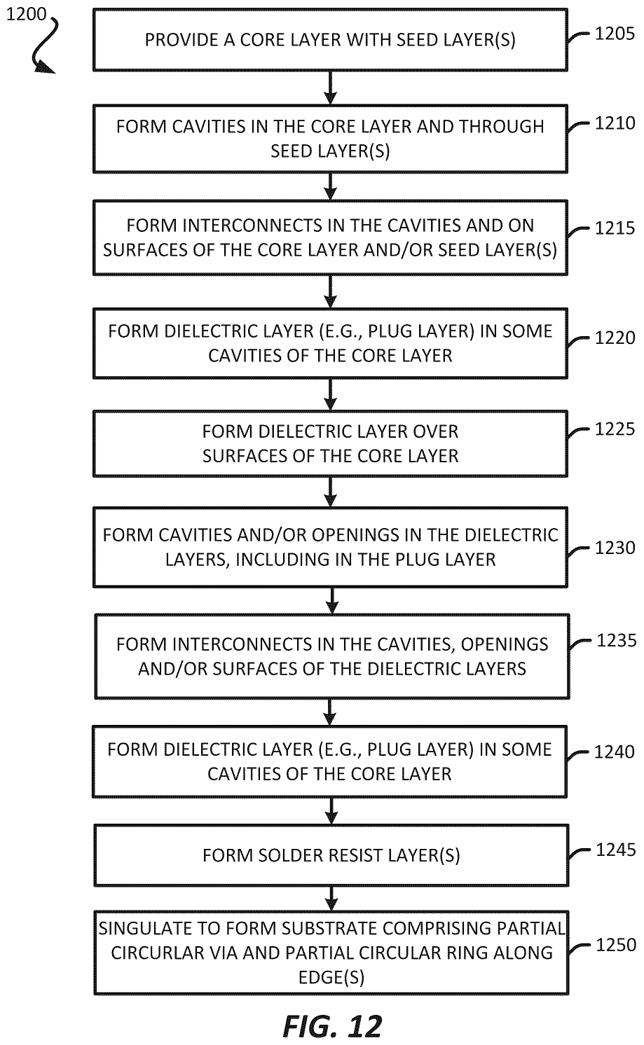

In some implementations, fabricating a substrate includes several processes. FIG. 12 illustrates an exemplary flow diagram of a method 1200 for providing or fabricating a substrate. In some implementations, the method 1200 of FIG. 12 may be used to provide or fabricate the substrate(s) of the disclosure. For example, the method 1200 of FIG. 12 may be used to fabricate the substrate 102.

It should be noted that the method 1200 of FIG. 12 may combine one or more processes in order to simplify and/or clarify the method for providing or fabricating a substrate. In some implementations, the order of the processes may be changed or modified.

The method provides (at 1205) a core layer with a first seed layer and a second seed layer. Stage 1 of FIG. 11A, illustrates and describes an example of a state after a core layer 120 is provided. A seed layer 1102 and a seed layer 1104 may be coupled to surfaces of the core layer 120. The core layer 120 may include a dielectric. The seed layer 1102 and/or the seed layer 1104 may include copper (Cu).

The method forms (at 1210) a plurality of cavities through the first seed layer, the core layer and the second seed layer. Stage 2 of FIG. 11A, illustrates and describes an example of a state after a the plurality of cavities 1101 and a plurality of cavities 1103 are formed through the seed layer 1102, the core layer 120 and the seed layer 1104. A laser ablation process may be used to form the plurality of cavities 1101 and/or the plurality of cavities 1103.

The method forms (at 1215) a plurality of interconnects in and on the core layer, the first seed layer and/or the second seed layer. Stage 3 of FIG. 11A, illustrates and describes an example of a state after a plurality of interconnects 1112, a plurality of interconnects 1113, a plurality of interconnects 1114 and a plurality of interconnects 1107 are formed. A lithography process, a plating process, a strip process and/or an etching process may be used to form the plurality of interconnects 1112, the plurality of interconnects 1113, the plurality of interconnects 1114 and the plurality of interconnects 1107. The plurality of interconnects 1112 may include interconnects formed on a first surface of the core layer 120 and/or seed layer 1102. The plurality of interconnects 1113 may include interconnects formed in the core layer 120. The plurality of interconnects 1114 may include interconnects formed on a second surface of the core layer 120 and/or seed layer 1104. As will be further described below, the plurality of interconnects 1107 may become a plurality of partial concentric interconnect structures (e.g., 107) for a substrate.

The method forms (at 1220) a plug dielectric layer in some of the plurality of cavities. Stage 4 of FIG. 11A, illustrates and describes an example of a state after a plug dielectric layer 125 is formed in the plurality of cavities 1101. The plug dielectric layer 125 may include a mold, a resin and/or an epoxy. Different implementations may use different dielectric materials for the plug dielectric layer 125. The plug dielectric layer 125 may be coupled to the plurality of interconnects 1107.

The method forms (at 1225) a dielectric layer over a first surface of the core layer and another dielectric layer over a second surface of the core layer. Stage 5 of FIG. 11B, illustrates and describes an example of a state after dielectric layer 1120 and the dielectric layer 1140 are formed. The dielectric layer 1120 are formed the plurality of interconnects 1112. The dielectric layer 1140 are formed over the plurality of interconnects 1114. A deposition and/or lamination process may be used to form the dielectric layer 1120 and/or the dielectric layer 1140. The dielectric layer 1120 and/or the dielectric layer 1140 may include prepreg and/or polyimide.

The method forms (at 1230) cavities and openings in the dielectric layers, including the plug dielectric layer. Stage 6 of FIG. 11B, illustrates and describes an example of a state after a plurality of cavities 1125, a plurality of cavities 1121 and a plurality of cavities 1141 are formed. The plurality of cavities 1125 may extend through the dielectric layer 1120, the plug dielectric layer 125 and the dielectric layer 1140. A laser ablation process may be used to form the plurality of cavities 1125. The plurality of cavities 1121 may be formed in the dielectric layer 1120. The plurality of cavities 1141 may be formed in the dielectric layer 1140. An exposure process and a development process may be used to form the plurality of cavities 1121 and the plurality of cavities 1141.

The method forms (at 1235) a plurality of interconnects. Stage 7 of FIG. 11B, illustrates and describes an example of a state after a plurality of interconnects 1122, a plurality of interconnects 1124 and a plurality of interconnects 1105 are formed. A lithography process, a plating process, a strip process and/or an etching process may be used to form the plurality of interconnects 1122, the plurality of interconnects 1124 and the plurality of interconnects 1105. The plurality of interconnects 1122 may include interconnects formed on a surface of the dielectric layer 1120. The plurality of interconnects 1124 may include interconnects formed on a surface of the dielectric layer 1140. As will be further described below, the plurality of interconnects 1105 may become a plurality of partial concentric interconnect structures (e.g., 105) for a substrate.

The method forms (at 1240) a plug dielectric layer in at least one cavity. Stage 8 of FIG. 11B, illustrates and describes an example of a state after a plug dielectric layer 127 is formed in the plurality of cavities 1125. The plug dielectric layer 127 may include a mold, a resin and/or an epoxy. Different implementations may use different dielectric materials for the plug dielectric layer 127. The plug dielectric layer 127 may be coupled to the plurality of interconnects 1105.

The method forms (at 1245) a plurality of solder resist layers. Stage 9 of FIG. 11B, illustrates and describes an example of a state after a solder resist layer 126 and a solder resist layer 128 are formed. A deposition process and/or lamination process may be used to form the solder resist layer 126 and/or the solder resist layer 128. The solder resist layer 126 and/or the solder resist layer 128 may include openings. An etching process, an exposure process and/or a development process may be used to form the openings in the solder resist layer 126 and/or the openings in the solder resist layer 128.

The method singulates (at 1250) a panel into substrates, where each substrate includes a plurality of partial concentric interconnect structures 105 and a plurality of partial concentric interconnect structures 107. Stage 10 of FIG. 11C, illustrates and describes an example of a state after a singulation process that cut a panel into individual substrates (e.g., 102a, 102b). The substrate 102a includes a plurality of partial concentric interconnect structures 105 and a plurality of partial concentric interconnect structures 107. The plurality of partial concentric interconnect structures 105 may be formed through the cutting along a cut line that includes the plurality of interconnects 1105. The plurality of partial concentric interconnect structures 107 may be formed through the cutting along a cut line that includes the plurality of interconnects 1107. The substrate 102a may include the core layer 120, a plurality of dielectric layers (e.g., 1120, 1140), a plurality of interconnects 121, a plurality of partial concentric interconnect structures 105 and a plurality of partial concentric interconnect structures 107, a solder resist layer 126 and a solder resist layer 128. The plurality of interconnects 121 may represent a plurality of interconnects 1112, a plurality of interconnects 1113, a plurality of interconnects 1114, a plurality of interconnects 1122 and/or a plurality of interconnects 1142.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Package Comprising Package Partial Coaxial Interconnect Structures

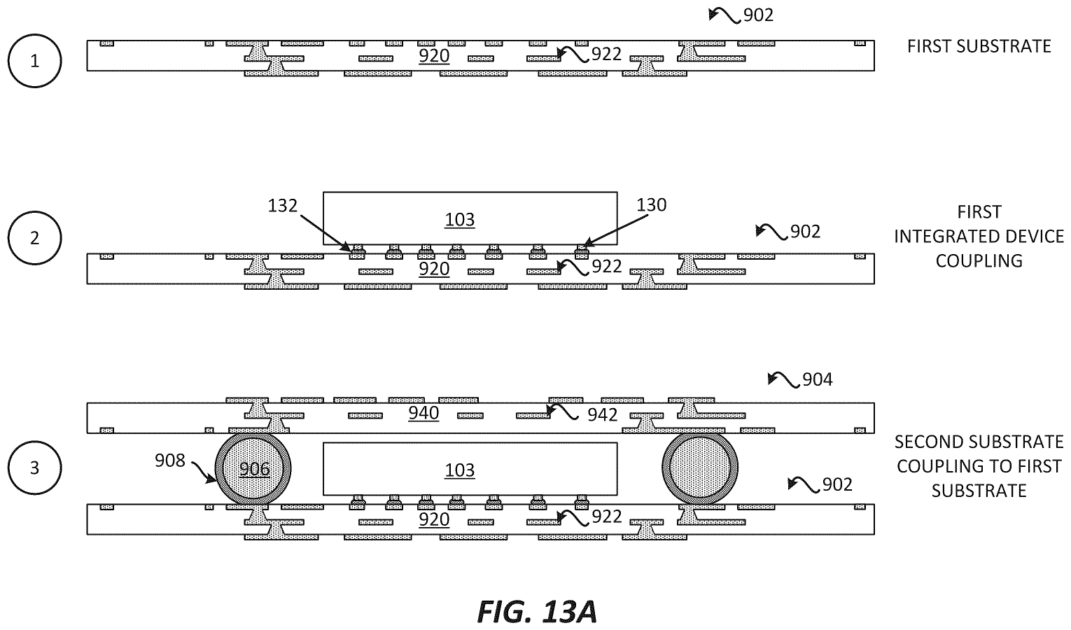

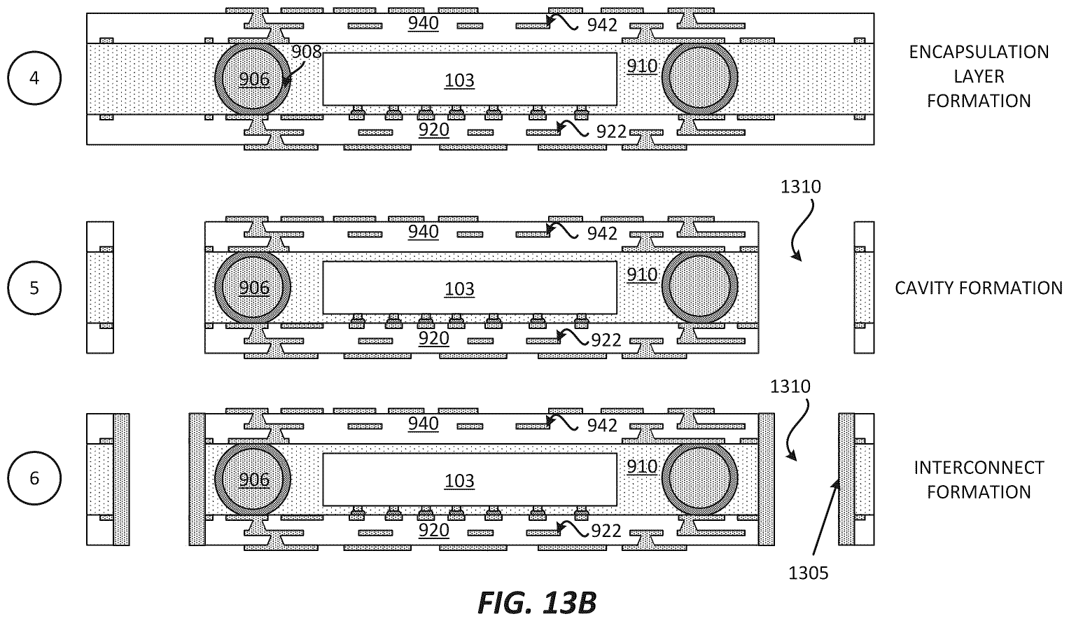

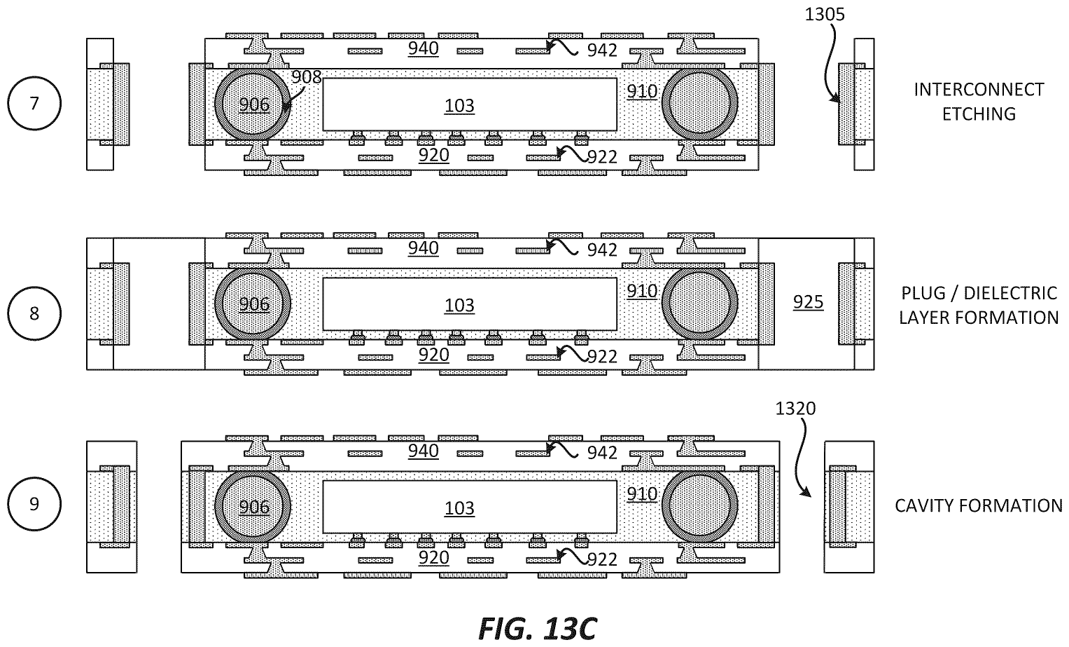

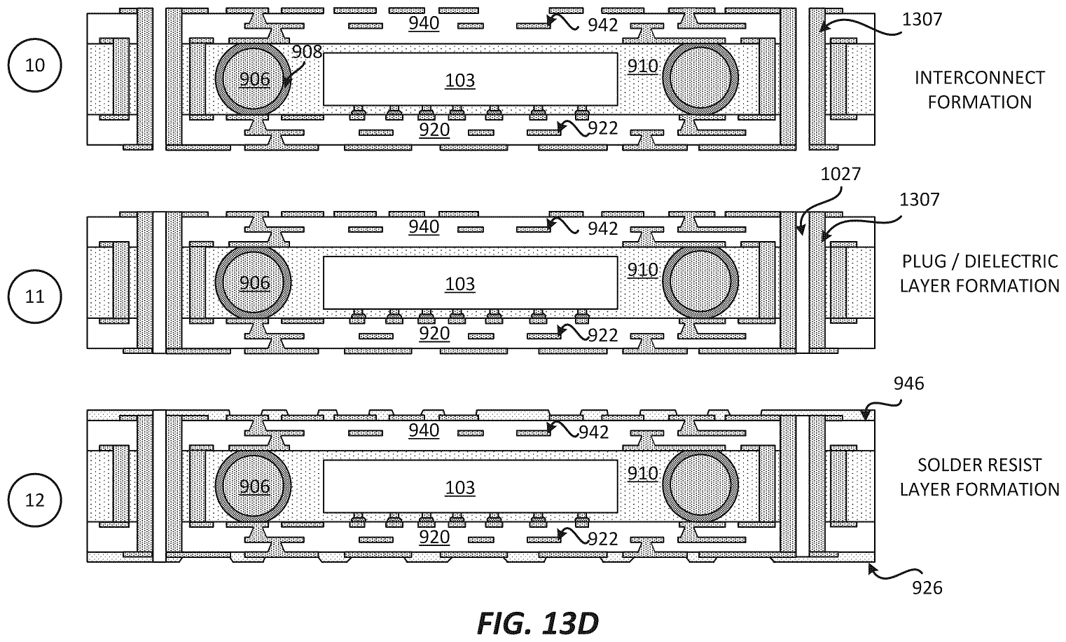

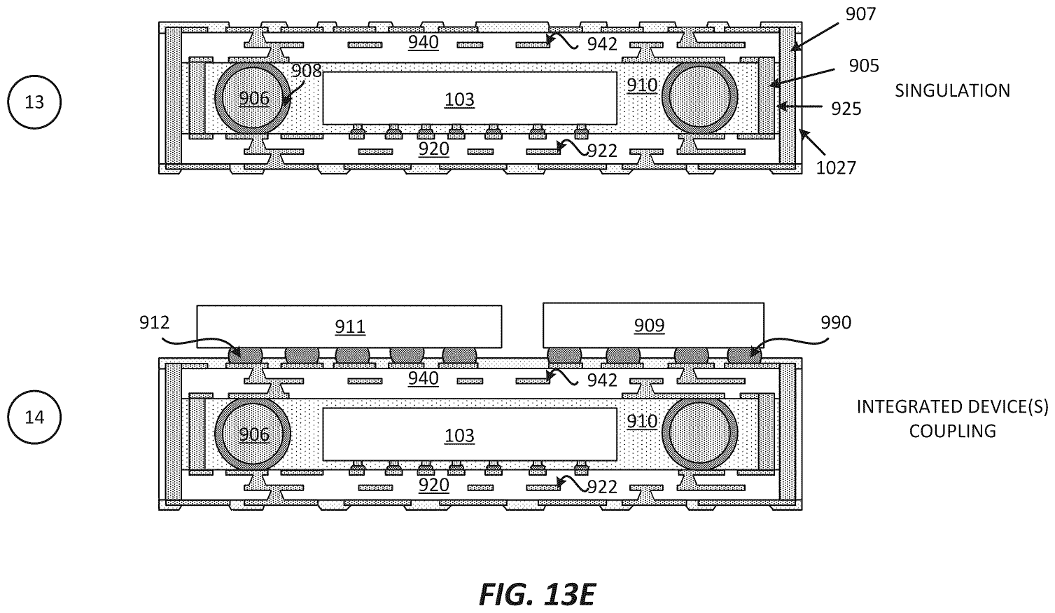

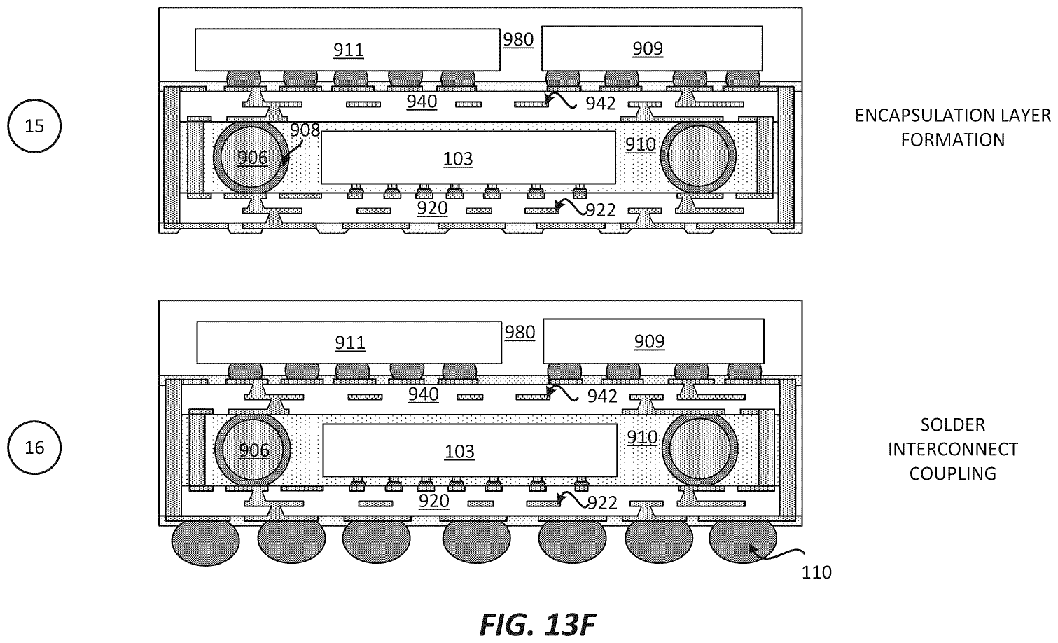

In some implementations, fabricating a package includes several processes. FIGS. 13A-13F illustrate an exemplary sequence for providing or fabricating a package. In some implementations, the sequence of FIGS. 13A-13F may be used to provide or fabricate the package 1000. However, the process of FIGS. 13A-13F may be used to fabricate any of the packages (e.g., 900) described in the disclosure.

It should be noted that the sequence of FIGS. 13A-13F may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

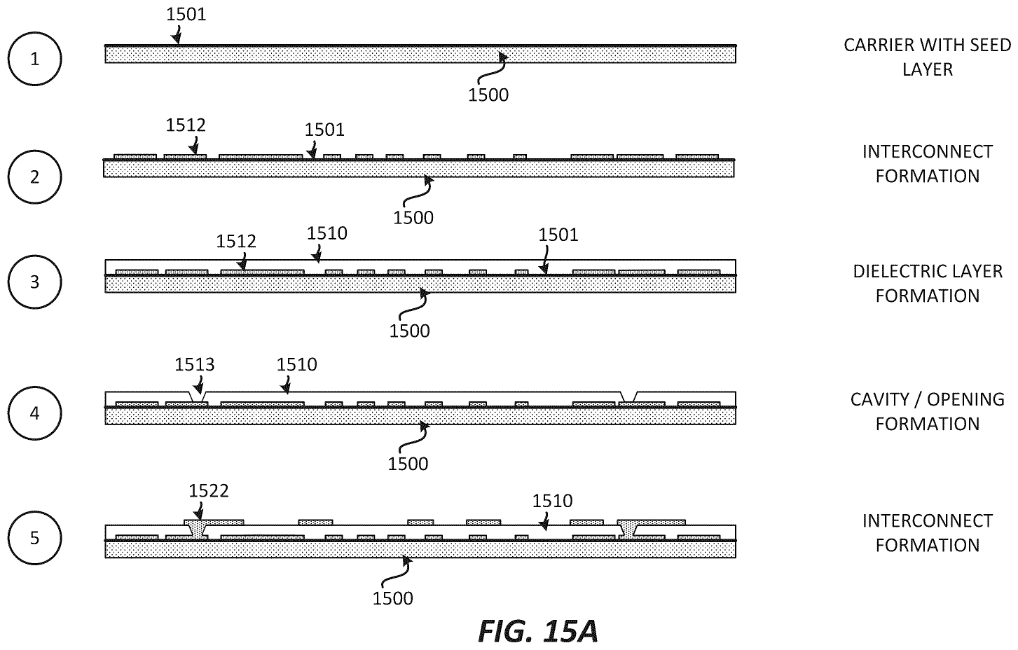

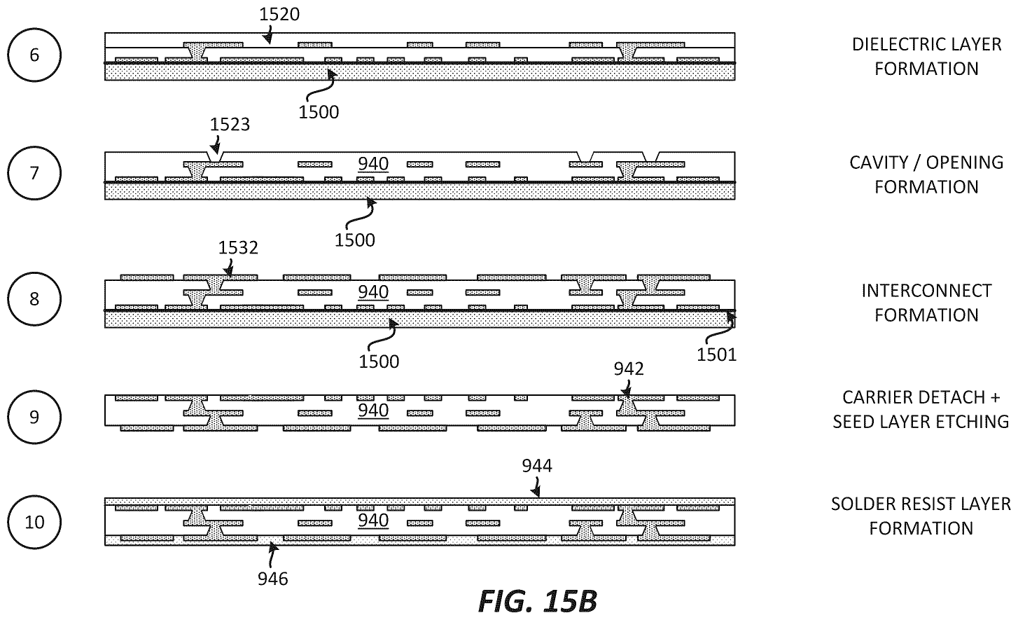

Stage 1, as shown in FIG. 13A, illustrates a state after a substrate 902 is provided. The substrate 902 may be a first substrate. The substrate 902 includes at least one dielectric layer 920 and a plurality of interconnects 922. The substrate 902 may include a first surface (e.g., top surface) and a second surface (e.g., bottom surface). The substrate 902 may include solder resist layers. The substrate 902 may be fabricated using the method as described in FIGS. 15A-15B.

Stage 2 illustrates a state after an integrated device 103 is coupled to the first surface (e.g., top surface) of the substrate 902. The integrated device 103 may be coupled to the substrate 902 through the plurality of pillar interconnects 130 and the plurality of solder interconnects 132. In some implementations, the integrated device 103 may be coupled to the substrate 902 through the plurality of solder interconnects 132. A solder reflow process may be used to couple the integrated device 103 to the substrate 902.

Stage 3 illustrates a state after a substrate 904 is provided and coupled to the substrate 102 through a plurality of package balls 906 and/or a plurality of solder interconnects 908. The plurality of package balls 906 may be optional. The substrate 904 may be a second substrate. The substrate 904 includes at least one dielectric layer 940 and a plurality of interconnects 942. The substrate 904 may include a first surface (e.g., top surface) and a second surface (e.g., bottom surface). The substrate 904 may include solder resist layers. The substrate 904 may be fabricated using the method as described in FIGS. 15A-15B. A solder reflow process may be used to couple the substrate 904 to the substrate 902 through the plurality of package balls 906 and the plurality of solder interconnects 908. The plurality of package balls 906 may be optional.

Stage 4, as shown in FIG. 13B, illustrates a state after an encapsulation layer 910 is provided between the substrate 902 and the substrate 904. The encapsulation layer 910 may at least partially encapsulate the integrated device 103, the plurality of package balls 906 and the plurality of solder interconnects 908. The encapsulation layer 910 may be located between the substrate 902 and the substrate 904. The encapsulation layer 910 may include a mold, a resin and/or an epoxy. The encapsulation layer 910 may be a means for encapsulation. The encapsulation layer 910 may be provided by using a compression and transfer molding process, a sheet molding process, or a liquid molding process.

Stage 5 illustrates a state after a plurality of cavities 1310 are formed. The plurality of cavities 1310 may extend through the substrate 904, the encapsulation layer 910 and the substrate 902. A laser ablation process may be used to form the plurality of cavities 1310.

Stage 6 illustrates a state after a plurality of interconnects 1305 are formed on side walls of the plurality of cavities 1310. A plating process may be used to form the plurality of interconnects 1305. The plurality of interconnects 1305 may be coupled to (i) interconnects from the plurality of interconnects 922 of the substrate 902 and (ii) interconnects from the plurality of interconnects 942 of the substrate 904. As will be further described below, the plurality of interconnects 1305 may be formed to become part of the plurality of partial concentric interconnect structures 905 of a package.

Stage 7, as shown in FIG. 13C, illustrates a state after portions of the plurality of interconnects 1305 are removed. An etching process may be used to remove portions of the plurality of interconnects 1305.

Stage 8 illustrates a state after a plug dielectric layer 925 is formed in the plurality of cavities 1310. The plug dielectric layer 925 may be coupled to the plurality of interconnects 1305. The plug dielectric layer 925 may include a mold, a resin and/or an epoxy. Different implementations may use different dielectric materials for the plug dielectric layer 925. The plug dielectric layer 925 may include a material that is different from the encapsulation layer 910.

Stage 9 illustrates a state after a plurality of cavities 1320 are formed. The plurality of cavities 1320 may extend through the plug dielectric layer 925. A laser ablation process may be used to form the plurality of cavities 1320.

Stage 10, as shown in FIG. 13D, illustrates a state after a plurality of interconnects 1307 are formed on side walls of the plurality of cavities 1320. A plating process may be used to form the plurality of interconnects 1307. The plurality of interconnects 1307 may be coupled to (i) interconnects from the plurality of interconnects 922 of the substrate 902 and (ii) interconnects from the plurality of interconnects 942 of the substrate 904. As will be further described below, the plurality of interconnects 1307 may be formed to become part of the plurality of partial concentric interconnect structures 907 of a package.

Stage 11 illustrates a state after a plug dielectric layer 1027 is formed in the plurality of cavities 1320. The plug dielectric layer 1027 may be coupled to the plurality of interconnects 1307. The plug dielectric layer 1027 may include a mold, a resin and/or an epoxy. Different implementations may use different dielectric materials for the plug dielectric layer 1027. The plug dielectric layer 1027 may include a material that is different from the encapsulation layer 910 and/or the plug dielectric layer 925.

Stage 12 illustrates a state after a solder resist layer 926 and a solder resist layer 946 are formed. The solder resist layer 926 may be coupled to the substrate 902. The solder resist layer 946 may be coupled to the substrate 904. A deposition process and/or lamination process may be used to form the solder resist layer 926 and/or the solder resist layer 946. The solder resist layer 926 and/or the solder resist layer 946 may include openings. An etching process, an exposure process and/or a development process may be used to form the openings in the solder resist layer 926 and/or the openings in the solder resist layer 946.

Stage 13, as shown in FIG. 13E, illustrates a state after singulation. A saw may be used to cut the package and/or a panel (e.g., substrate panel) along a cut line and/or cut region that includes portions of the plug dielectric layer 1027. After singulation, the package may include a plurality of partial concentric interconnect structures 905 and a plurality of partial concentric interconnect structures 907. The plurality of partial concentric interconnect structures 905 may be formed through the cutting along a cut line that includes the plurality of interconnects 1305. The plurality of partial concentric interconnect structures 907 may be formed through the cutting along a cut line that includes the plurality of interconnects 1307. The plug dielectric layer 925 may be located laterally between the plurality of partial concentric interconnect structures 905 and the plurality of partial concentric interconnect structures 907. The plug dielectric layer 1027 may be coupled to the plurality of partial concentric interconnect structures 905 and/or the plurality of partial concentric interconnect structures 907. The plurality of partial concentric interconnect structures 905 and the plurality of partial concentric interconnect structures 907 may define a plurality of partial coaxial interconnect structures.

Stage 14 illustrates a state after the integrated device 909 is coupled to the substrate 904 through a plurality of solder interconnects 990. Stage 14 also illustrates a state after the integrated device 911 is coupled to the substrate 904 through a plurality of solder interconnects 912. A solder reflow process may be used to couple the integrated device 909 and the integrated device 911 to the substrate 904, through a plurality of solder interconnects.

Stage 15, as shown in FIG. 13F, illustrates a state after an encapsulation layer 980 is provided and coupled to the substrate 904. The encapsulation layer 980 may at least partially encapsulate the integrated device 909 and the integrated device 911. The encapsulation layer 980 may include a mold, a resin and/or an epoxy. The encapsulation layer 980 may be a means for encapsulation. The encapsulation layer 980 may be provided by using a compression and transfer molding process, a sheet molding process, or a liquid molding process.

Stage 16 illustrates a state after a plurality of solder interconnects 110 are coupled to the second surface of the substrate 902. A solder reflow process may be used to couple the plurality of solder interconnects 110 to the substrate 902. Stage 16 may illustrate the package 1000.

### Exemplary Flow Diagram of a Method for Fabricating a Package Comprising Package Partial Coaxial Interconnect Structures

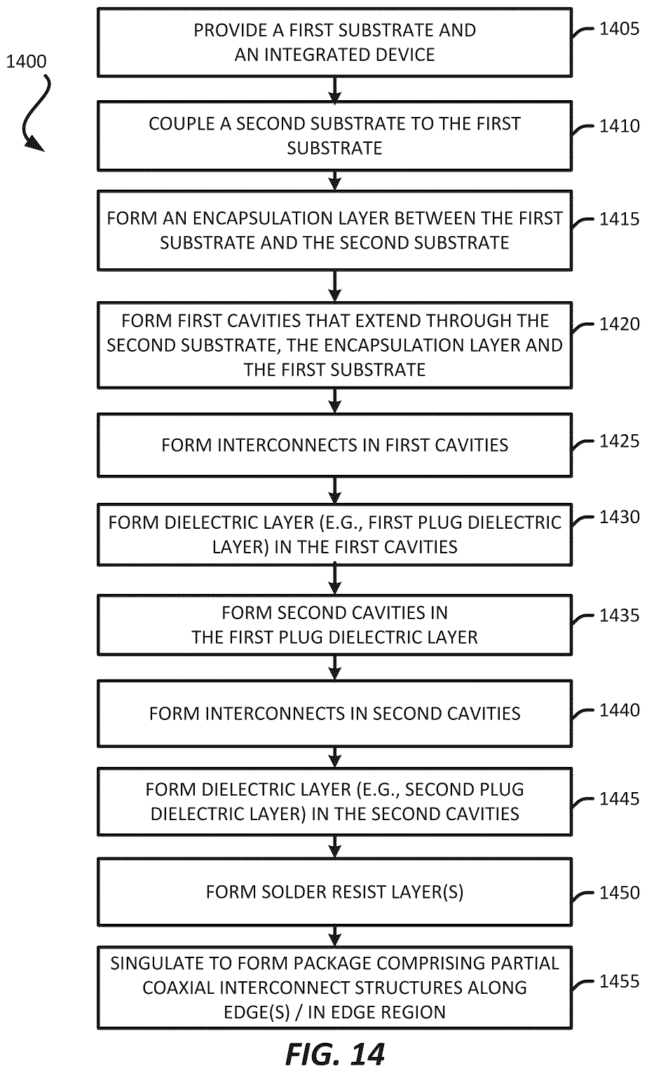

In some implementations, fabricating a package includes several processes. FIG. 14 illustrates an exemplary flow diagram of a method 1400 for providing or fabricating a package. In some implementations, the method 1400 of FIG. 14 may be used to provide or fabricate the package 1000 described in the disclosure. However, the method 1400 may be used to provide or fabricate any of the packages (e.g., 900) described in the disclosure.

It should be noted that the method 1400 of FIG. 14 may combine one or more processes in order to simplify and/or clarify the method for providing or fabricating a package. In some implementations, the order of the processes may be changed or modified.

The method provides (at 1405) a first substrate and an integrated device coupled to the first substrate. Stage 1 of FIG. 13A, illustrates and describes an example of a state after a substrate 902 is provided. The substrate 902 may be a first substrate. The substrate 902 includes at least one dielectric layer 920 and a plurality of interconnects 922. The substrate 902 may include a first surface (e.g., top surface) and a second surface (e.g., bottom surface). The substrate 902 may include solder resist layers. The substrate 902 may be fabricated using the method as described in FIGS. 15A-15B.

Stage 2 of FIG. 13A, illustrates and describes an example of a state after an integrated device 103 is coupled to the first surface (e.g., top surface) of the substrate 902. The integrated device 103 may be coupled to the substrate 902 through the plurality of pillar interconnects 130 and the plurality of solder interconnects 132. In some implementations, the integrated device 103 may be coupled to the substrate 902 through the plurality of solder interconnects 132. A solder reflow process may be used to couple the integrated device 103 to the substrate 902.

The method couples (at 1410) a second substrate to the first substrate through a plurality of solder interconnects and/or a plurality of package balls. Stage 3 of FIG. 13A, illustrates and describes an example of a state after a substrate 904 is provided and coupled to the substrate 102 through a plurality of package balls 906 and/or a plurality of solder interconnects 908. The plurality of package balls 906 may be optional. The substrate 904 may be a second substrate. The substrate 904 includes at least one dielectric layer 940 and a plurality of interconnects 942. The substrate 904 may include a first surface (e.g., top surface) and a second surface (e.g., bottom surface). The substrate 904 may include solder resist layers. The substrate 904 may be fabricated using the method as described in FIGS. 15A-15B. A solder reflow process may be used to couple the substrate 904 to the substrate 902 through the plurality of package balls 906 and the plurality of solder interconnects 908.

The method forms (at 1415) an encapsulation layer between the first substrate and the second substrate. Stage 4 of FIG. 13B, illustrates and describes an example of a state after an encapsulation layer 910 is provided between the substrate 902 and the substrate 904. The encapsulation layer 910 may at least partially encapsulate the integrated device 103, the plurality of package balls 906 and the plurality of solder interconnects 908. The encapsulation layer 910 may be located between the substrate 902 and the substrate 904. The encapsulation layer 910 may include a mold, a resin and/or an epoxy. The encapsulation layer 910 may be a means for encapsulation. The encapsulation layer 910 may be provided by using a compression and transfer molding process, a sheet molding process, or a liquid molding process.

The method forms (at 1420) a first plurality of cavities that extend through the first substrate, the encapsulation layer and the second substrate. Stage 5 of FIG. 13B, illustrates and describes an example of a state after a plurality of cavities 1310 are formed. The plurality of cavities 1310 may extend through the substrate 904, the encapsulation layer 910 and the substrate 902. A laser ablation process may be used to form the plurality of cavities 1310.

The method forms (at 1425) a plurality of interconnects in the first plurality of cavities. Stage 6 of FIG. 13B, illustrates and describes an example of a state after a plurality of interconnects 1305 are formed on side walls of the plurality of cavities 1310. A plating process may be used to form the plurality of interconnects 1305. The plurality of interconnects 1305 may be coupled to (i) interconnects from the plurality of interconnects 922 of the substrate 902 and (ii) interconnects from the plurality of interconnects 942 of the substrate 904. As will be further described below, the plurality of interconnects 1305 may be formed to become part of the plurality of partial concentric interconnect structures 905 of a package.

Forming (at 1425) the plurality of interconnects may also include removing portions of the interconnects. Stage 7 of FIG. 13C, illustrates and describes an example of a state after portions of the plurality of interconnects 1305 are removed. An etching process may be used to remove portions of the plurality of interconnects 1305.

The method forms (at 1430) a first plug dielectric layer in the first plurality of cavities. Stage 8 of FIG. 13C, illustrates and describes an example of a state after a plug dielectric layer 925 is formed in the plurality of cavities 1310. The plug dielectric layer 925 may be coupled to the plurality of interconnects 1305. The plug dielectric layer 925 may include a mold, a resin and/or an epoxy. Different implementations may use different dielectric materials for the plug dielectric layer 925. The plug dielectric layer 925 may include a material that is different from the encapsulation layer 910.

The method forms (at 1435) a second plurality of cavities in the plug dielectric layer. Stage 9 of FIG. 13C, illustrates and describes an example of a state after a plurality of cavities 1320 are formed. The plurality of cavities 1320 may extend through the plug dielectric layer 925. A laser ablation process may be used to form the plurality of cavities 1320.

The method forms (at 1440) a plurality of interconnects in the second plurality of cavities. Stage 10 of FIG. 13D, illustrates and describes an example of a state after a plurality of interconnects 1307 are formed on side walls of the plurality of cavities 1320. A plating process may be used to form the plurality of interconnects 1307. The plurality of interconnects 1307 may be coupled to (i) interconnects from the plurality of interconnects 922 of the substrate 902 and (ii) interconnects from the plurality of interconnects 942 of the substrate 904. As will be further described below, the plurality of interconnects 1307 may be formed to become part of the plurality of partial concentric interconnect structures 907 of a package.

The method forms (at 1445) a second plug dielectric layer in the second plurality of cavities. Stage 11 of FIG. 13D, illustrates and describes an example of a state after a plug dielectric layer 1027 is formed in the plurality of cavities 1320. The plug dielectric layer 1027 may be coupled to the plurality of interconnects 1307. The plug dielectric layer 1027 may include a mold, a resin and/or an epoxy. Different implementations may use different dielectric materials for the plug dielectric layer 1027. The plug dielectric layer 1027 may include a material that is different from the encapsulation layer 910 and/or the plug dielectric layer 925.

The method forms (at 1450) at least one solder resist layer. Stage 12 of FIG. 13D, illustrates and describes an example of a state after a solder resist layer 926 and a solder resist layer 946 are formed. The solder resist layer 926 may be coupled to the substrate 902. The solder resist layer 946 may be coupled to the substrate 904. A deposition process and/or lamination process may be used to form the solder resist layer 926 and/or the solder resist layer 946. The solder resist layer 926 and/or the solder resist layer 946 may include openings. An etching process, an exposure process and/or a development process may be used to form the openings in the solder resist layer 926 and/or the openings in the solder resist layer 946.

The method singulates (at 1455) a panel to form a package with partial coaxial interconnect structures along edges and/or in edge region of the package. Stage 13 of FIG. 13E, illustrates and describes an example of a state after singulation. A saw may be used to cut the package and/or a panel along a cut line that includes portions of the plug dielectric layer 1027. After singulation, the package may include a plurality of partial concentric interconnect structures 905 and a plurality of partial concentric interconnect structures 907. The plurality of partial concentric interconnect structures 905 may be formed through the cutting along a cut line that includes the plurality of interconnects 1305. The plurality of partial concentric interconnect structures 907 may be formed through the cutting along a cut line that includes the plurality of interconnects 1307. The plug dielectric layer 925 may be located laterally between the plurality of partial concentric interconnect structures 905 and the plurality of partial concentric interconnect structures 907. The plug dielectric layer 1027 may be coupled to the plurality of partial concentric interconnect structures 905 and/or the plurality of partial concentric interconnect structures 907. The plurality of partial concentric interconnect structures 905 and the plurality of partial concentric interconnect structures 907 may define a plurality of partial coaxial interconnect structures.

After singulation, the method may perform additional steps and/or processes. For example, the method may couple additional integrated devices to the substrates, form and couple an additional encapsulation layer to the package, and couple solder interconnects to the package.

Stage 14 of FIG. 13E, illustrates and describes an example of a state after the integrated device 909 is coupled to the substrate 904 through a plurality of solder interconnects 990. Stage 14 also illustrates a state after the integrated device 911 is coupled to the substrate 904 through a plurality of solder interconnects 912. A solder reflow process may be used to couple the integrated device 909 and the integrated device 911 to the substrate 904, through a plurality of solder interconnects.

Stage 15 of FIG. 13F, illustrates and describes an example of a state after an encapsulation layer 980 is provided and coupled to the substrate 904. The encapsulation layer 980 may at least partially encapsulate the integrated device 909 and the integrated device 911. The encapsulation layer 980 may include a mold, a resin and/or an epoxy. The encapsulation layer 980 may be a means for encapsulation. The encapsulation layer 980 may be provided by using a compression and transfer molding process, a sheet molding process, or a liquid molding process.

Stage 16 of FIG. 13F, illustrates and describes an example of a state after a plurality of solder interconnects 110 are coupled to the second surface of the substrate 902. A solder reflow process may be used to couple the plurality of solder interconnects 110 to the substrate 902. Stage 16 may illustrate the package 900.

### Exemplary Sequence for Fabricating a Substrate

In some implementations, fabricating a substrate includes several processes. FIGS. 15A-15B illustrate an exemplary sequence for providing or fabricating a substrate. In some implementations, the sequence of FIGS. 15A-15B may be used to provide or fabricate the substrate 904. However, the process of FIGS. 15A-15B may be used to fabricate any of the substrates (e.g., 902) described in the disclosure.

It should be noted that the sequence of FIGS. 15A-15B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 15A, illustrates a state after a carrier 1500 is provided. A seed layer 1501 may be located over the carrier 1500.

Stage 2 illustrates a state after a plurality of interconnects 1512 are formed. The interconnects 1512 may be located over the seed layer 1501. A lithography process, a plating process, a strip process and/or an etching process may be used to form the plurality of interconnects 1512. The interconnects 1512 may represent at least some of the interconnects from the plurality of interconnects 942.

Stage 3 illustrates a state after a dielectric layer 1510 is formed over the carrier 1500, the seed layer 1501 and the plurality of interconnects 1512. A deposition and/or lamination process may be used to form the dielectric layer 1510. The dielectric layer 1510 may include prepreg and/or polyimide. The dielectric layer 1510 may include a photo-imagable dielectric. However, different implementations may use different materials for the dielectric layer.

Stage 4 illustrates a state after a plurality of cavities 1513 is formed in the dielectric layer 1510. The plurality of cavities 1513 may be formed using an etching process (e.g., photo etching process), a laser process, an exposure process and/or a development process.

Stage 5 illustrates a state after interconnects 1522 are formed in and over the dielectric layer 1510, including in and over the plurality of cavities 1513. For example, a via, pad and/or traces may be formed. A lithography process, a plating process, a strip process and/or an etching process may be used to form the interconnects.

Stage 6, as shown in FIG. 15B, illustrates a state after a dielectric layer 1520 is formed over the dielectric layer 1510 and the plurality of interconnects 1522. A deposition and/or lamination process may be used to form the dielectric layer 1520. The dielectric layer 1520 may include prepreg and/or polyimide. The dielectric layer 1520 may include a photo-imagable dielectric. However, different implementations may use different materials for the dielectric layer.

Stage 7, illustrates a state after a plurality of cavities 1523 is formed in the dielectric layer 940. The dielectric layer 940 may represent the dielectric layer 1510 and/or the dielectric layer 1520. The plurality of cavities 1523 may be formed using an etching process (e.g., photo etching process), a laser process, an exposure process and/or a development process.

Stage 8 illustrates a state after interconnects 1532 are formed in and over the dielectric layer 940, including in and over the plurality of cavities 1523. For example, a via, pad and/or traces may be formed. A lithography process, a plating process, a strip process and/or an etching process may be used to form the interconnects.

Stage 9 illustrates a state after the carrier 1500 is decoupled (e.g., detached, removed, grinded out) from at least one dielectric layer 940 and the seed layer 1501, portions of the seed layer 1501 are removed (e.g., etched out), leaving the substrate 904 that includes at least one dielectric layer 940 and the plurality of interconnects 942. The plurality of interconnects 942 may represent the plurality of interconnects 1512, the plurality of interconnects 1522 and/or the plurality of interconnects 1532.

Stage 10 illustrates a state after the solder resist layer 944 is formed over the first surface of the substrate 904, and after the solder resist layer 946 is formed over the second surface of the substrate 904. A deposition process and/or lamination process may be used to form the solder resist layer 944 and/or the solder resist layer 946. The solder resist layer 944 and/or the solder resist layer 946 may include openings. An etching process, an exposure process and/or a development process may be used to form the openings in the solder resist layer 944 and/or the openings in the solder resist layer 946.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

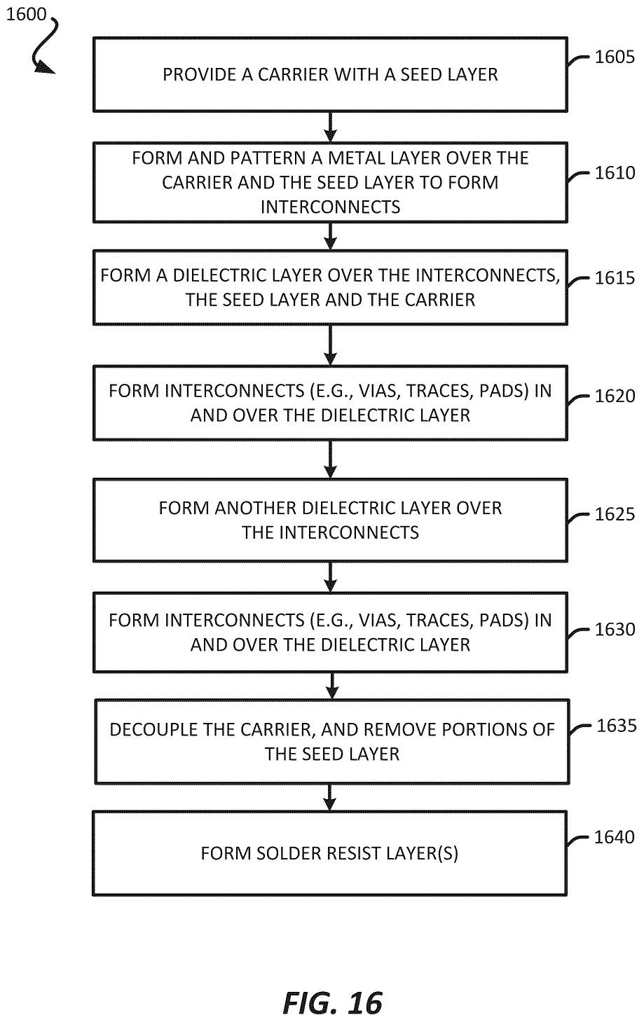

In some implementations, fabricating a substrate includes several processes. FIG. 16 illustrates an exemplary flow diagram of a method 1600 for providing or fabricating a substrate. In some implementations, the method 1600 of FIG. 16 may be used to provide or fabricate the substrate(s) of the disclosure. For example, the method 1600 of FIG. 16 may be used to fabricate the substrate 904.

It should be noted that the method 1600 of FIG. 16 may combine one or more processes in order to simplify and/or clarify the method for providing or fabricating a substrate. In some implementations, the order of the processes may be changed or modified.

The method provides (at 1605) a carrier with a seed layer. Stage 1 of FIG. 15A, illustrates and describes an example of a state after a carrier 1500 is provided. A seed layer 1501 may be located over the carrier 1500.

The method forms and patterns (at 1610) a plurality of interconnects. Stage 2 of FIG. 15A, illustrates and describes an example of a state after a plurality of interconnects 1512 are formed. The interconnects 1512 may be located over the seed layer 1501. A lithography process, a plating process, a strip process and/or an etching process may be used to form the plurality of interconnects 1512. The interconnects 1512 may represent at least some of the interconnects from the plurality of interconnects 942.

The method forms (at 1615) a dielectric layer. Stage 3 of FIG. 15A, illustrates and describes an example of a state after a dielectric layer 1510 is formed over the carrier 1500, the seed layer 1501 and the plurality of interconnects 1512. A deposition and/or lamination process may be used to form the dielectric layer 1510. The dielectric layer 1510 may include prepreg and/or polyimide. The dielectric layer 1510 may include a photo-imagable dielectric. However, different implementations may use different materials for the dielectric layer.

The method forms (at 1620) a plurality of interconnects. Forming a plurality of interconnects may including forming a plurality of cavities in a dielectric layer and a performing a plating process. Stage 4 of FIG. 15A, illustrates and describes an example of a state after a plurality of cavities 1513 is formed in the dielectric layer 1510. The plurality of cavities 1513 may be formed using an etching process (e.g., photo etching process), a laser process, an exposure process and/or a development process.

Stage 5 of FIG. 15A, illustrates and describes an example of a state after interconnects 1522 are formed in and over the dielectric layer 1510, including in and over the plurality of cavities 1513. For example, a via, pad and/or traces may be formed. A lithography process, a plating process, a strip process and/or an etching process may be used to form the interconnects.

The method forms (at 1625) another dielectric layer. Stage 6 of FIG. 15B, illustrates and describes an example of a state after a dielectric layer 1520 is formed over the dielectric layer 1510 and the plurality of interconnects 1522. A deposition and/or lamination process may be used to form the dielectric layer 1520. The dielectric layer 1520 may include prepreg and/or polyimide. The dielectric layer 1520 may include a photo-imagable dielectric. However, different implementations may use different materials for the dielectric layer.

The method forms (at 1630) a plurality of interconnects. Forming a plurality of interconnects may including forming a plurality of cavities in a dielectric layer and a performing a plating process. Stage 7 of FIG. 15B, illustrates and describes an example of a state after a plurality of cavities 1523 is formed in the dielectric layer 940. The dielectric layer 940 may represent the dielectric layer 1510 and/or the dielectric layer 1520. The plurality of cavities 1523 may be formed using an etching process (e.g., photo etching process), a laser process, an exposure process and/or a development process.

Stage 8 of FIG. 15B, illustrates and describes an example of a state after interconnects 1532 are formed in and over the dielectric layer 940, including in and over the plurality of cavities 1523. For example, a via, pad and/or traces may be formed. A lithography process, a plating process, a strip process and/or an etching process may be used to form the interconnects.

The method decouples (at 1635) a carrier. Stage 8 of FIG. 15B, illustrates and describes an example of a state after the carrier 1500 is decoupled (e.g., detached, removed, grinded out) from at least one dielectric layer 940 and the seed layer 1501, portions of the seed layer 1501 are removed (e.g., etched out), leaving the substrate 102 that includes at least one dielectric layer 940 and the plurality of interconnects 942. The plurality of interconnects 942 may represent the plurality of interconnects 1512, the plurality of interconnects 1522 and/or the plurality of interconnects 1532.

The method forms (at 1640) solder resist layers. Stage 10 of FIG. 15B, illustrates and describes an example of a state after the solder resist layer 944 is formed over the first surface of the substrate 904, and after the solder resist layer 946 is formed over the second surface of the substrate 904. A deposition process and/or lamination process may be used to form the solder resist layer 944 and/or the solder resist layer 946. An etching process, an exposure process and/or a development process may be used to form the openings in the solder resist layer 944 and/or the openings in the solder resist layer 946.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

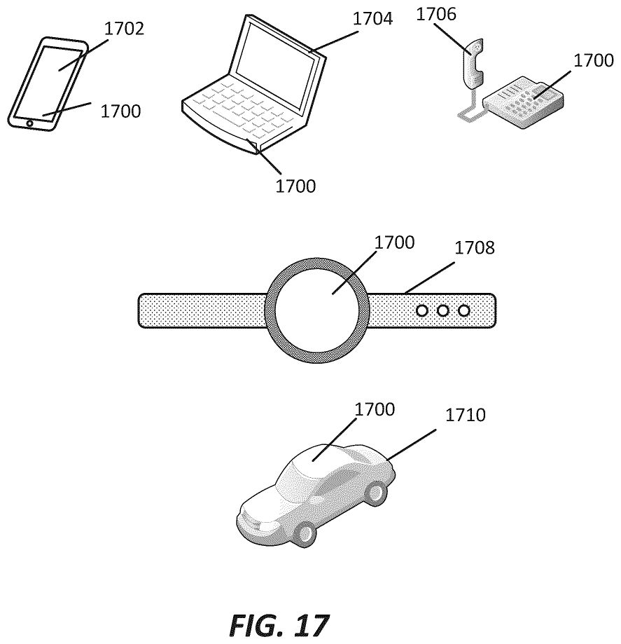

FIG. 17 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1702, a laptop computer device 1704, a fixed location terminal device 1706, a wearable device 1708, or automotive vehicle 1710 may include a device 1700 as described herein. The device 1700 may be, for example, any of the devices and/or integrated circuit (IC) packages described herein. The devices 1702, 1704, 1706 and 1708 and the vehicle 1710 illustrated in FIG. 17 are merely exemplary. Other electronic devices may also feature the device 1700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-10, 11A-11C, 12, 13A-13F, 14, 15A-15B and 16-17 may be rearranged and/or combined into a single component, process, feature or function or embodied in several components, processes, or functions. Additional elements, components, processes, and/or functions may also be added without departing from the disclosure. It should also be noted FIGS. 1-10, 11A-11C, 12, 13A-13F, 14, 15A-15B and 16-17 and its corresponding description in the present disclosure is not limited to dies and/or ICs. In some implementations, FIGS. 1-10, 11A-11C, 12, 13A-13F, 14, 15A-15B and 16-17 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising an integrated device; and a substrate coupled to the integrated device through at least a plurality of solder interconnects, wherein the substrate comprises a plurality of interconnects, and wherein the plurality of interconnects comprises a first via interconnect comprising a partial concentric planar cross section; and a second via interconnect comprising a partial ring planar cross section, wherein the second via interconnect laterally surrounds at least part of the first via interconnect.

Aspect 2: The package of aspect 1, wherein the first via interconnect comprises a semi concentric planar cross section.

Aspect 3: The package of aspects 1 through 2, wherein the first via interconnect is configured to provide a first electrical path for power; and wherein the second via interconnect is configured to provide a second electrical path for ground.

Aspect 4: The package of aspects 1 through 3, further comprising a first pad interconnect coupled to the first via interconnect, wherein the first pad interconnect comprises a first partial concentric planar cross section; a second pad interconnect coupled to the first via interconnect, wherein the second pad interconnect comprises a second partial concentric planar cross section; a third pad interconnect coupled to the second via interconnect, wherein the third pad interconnect comprises a third partial concentric planar cross section; and a fourth pad interconnect coupled to the second via interconnect, wherein the fourth pad interconnect comprises a fourth partial concentric planar cross section.

Aspect 5: The package of aspects 1 through 4, wherein the plurality of interconnects comprises a plurality of first via interconnects, where each first via interconnect comprises a partial concentric planar cross section; and a plurality of second via interconnects, where each second via interconnect comprises a partial ring planar cross section.

Aspect 6: The package of aspect 5, wherein the plurality of first via interconnects and the plurality of second via interconnects are located along at least one edge of the package.

Aspect 7: The package of aspects 5 through 6, wherein the plurality of second via interconnects are configured as an electromagnetic interference shield.

Aspect 8: The package of aspects 1 through 7, wherein the substrate comprises a core layer; and a plug dielectric layer located laterally to the core layer, wherein the first via interconnect extends through the core layer, wherein the second via interconnect extends through the core layer, wherein the plug dielectric layer includes a different material from the core layer, and wherein the plug dielectric layer is located laterally between the first via interconnect and the second via interconnect.

Aspect 9: The package of aspect 8, wherein the substrate further comprises a second plug dielectric layer coupled to the first via interconnect, wherein the second plug dielectric layer is located on a side surface of the substrate, and wherein the second plug dielectric layer is located at least laterally to the core layer.

Aspect 10: A substrate comprising at least one dielectric layer; and a plurality of interconnects comprising a first via interconnect comprising a partial concentric planar cross section; and a second via interconnect comprising a partial ring planar cross section, wherein the second via interconnect laterally surrounds at least part of the first via interconnect.

Aspect 11: The substrate of aspect 10, further comprising a first pad interconnect coupled to the first via interconnect, wherein the first pad interconnect comprises a first partial concentric planar cross section; a second pad interconnect coupled to the first via interconnect, wherein the second pad interconnect comprises a second partial concentric planar cross section; a third pad interconnect coupled to the second via interconnect, wherein the third pad interconnect comprises a third partial concentric planar cross section; and a fourth pad interconnect coupled to the second via interconnect, wherein the fourth pad interconnect comprises a fourth partial concentric planar cross section.

Aspect 12: The substrate of aspects 10 through 11, wherein the plurality of interconnects comprises a plurality of first via interconnects, where each first via interconnect comprises a partial concentric planar cross section; and a plurality of second via interconnects, where each second via interconnect comprises a partial ring planar cross section.

Aspect 13: The substrate of aspect 12, wherein the plurality of first via interconnects and the plurality of second via interconnects are located along at least one edge of the substrate.

Aspect 14: The substrate of aspects 10 through 13, wherein the substrate comprises a core layer; and a plug dielectric layer located laterally to the core layer, wherein the at least one dielectric layer comprises a first dielectric layer coupled to a first surface of the core layer; and a second dielectric layer coupled to a second surface of the core layer, wherein the first via interconnect extends through the core layer, the first dielectric layer and the second dielectric layer, wherein the second via interconnect extends through the core layer, wherein the plug dielectric layer includes a different material from the core layer, and wherein the plug dielectric layer is located laterally between the first via interconnect and the second via interconnect.

Aspect 15: A package comprising a first substrate; a first integrated device coupled to the first substrate; a second substrate; an encapsulation layer located between the first substrate and the second substrate, wherein the encapsulation layer is coupled to the first substrate and the second substrate; and a plurality of package interconnects comprising a first package via interconnect comprising a partial concentric planar cross section; and a second package via interconnect comprising a partial ring planar cross section, wherein the second via interconnect laterally surrounds at least part of the first via interconnect.

Aspect 16: The package of aspect 15, further comprising a first pad interconnect coupled to the first package via interconnect, wherein the first pad interconnect comprises a first partial concentric planar cross section; a second pad interconnect coupled to the first package via interconnect, wherein the second pad interconnect comprises a second partial concentric planar cross section; a third pad interconnect coupled to the second package via interconnect, wherein the third pad interconnect comprises a third partial concentric planar cross section; and a fourth pad interconnect coupled to the second package via interconnect, wherein the fourth pad interconnect comprises a fourth partial concentric planar cross section.

Aspect 17: The package of aspect 16, wherein the first pad interconnect and the third pad interconnect are interconnects of the first substrate, and wherein the second pad interconnect and the fourth pad interconnect are interconnects of the second substrate.

Aspect 18: The package of aspects 15 through 17, wherein the first package via interconnect extends through at least part of the first substrate, the encapsulation layer and the second substrate, and wherein the second package via interconnect extends through at least part of the encapsulation layer.

Aspect 19: The package of aspects 15 through 18, wherein the first package via interconnect is configured to provide a first electrical path for ground; and wherein the second package via interconnect is configured to provide a second electrical path for power.

Aspect 20: The package of aspect 19, further comprising a second integrated device coupled to the second substrate, wherein power to the second integrated device travels through an electrical path that includes the second package via interconnect.

Aspect 21: The package of aspects 15 through 19, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 22: The package of aspects 1 through 9, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 21: The substrate of aspects 10 through 14, wherein the substrate is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
an integrated device; and
a substrate coupled to the integrated device through at least a plurality of solder interconnects,
wherein the substrate comprises a plurality of interconnects, and
wherein the plurality of interconnects comprises:
a first via interconnect comprising a partial concentric planar cross section; and
a second via interconnect comprising a partial ring planar cross section, wherein the second via interconnect laterally surrounds at least part of the first via interconnect.

2. The package of claim 1, wherein the first via interconnect comprises a semi concentric planar cross section.

3. The package of claim 1,
wherein the first via interconnect is configured to provide a first electrical path for power; and
wherein the second via interconnect is configured to provide a second electrical path for ground.

4. The package of claim 1, further comprising:
a first pad interconnect coupled to the first via interconnect, wherein the first pad interconnect comprises a first partial concentric planar cross section;
a second pad interconnect coupled to the first via interconnect, wherein the second pad interconnect comprises a second partial concentric planar cross section;
a third pad interconnect coupled to the second via interconnect, wherein the third pad interconnect comprises a third partial concentric planar cross section; and
a fourth pad interconnect coupled to the second via interconnect, wherein the fourth pad interconnect comprises a fourth partial concentric planar cross section.

5. The package of claim 1, wherein the plurality of interconnects comprises:
a plurality of first via interconnects, where each first via interconnect comprises a partial concentric planar cross section; and
a plurality of second via interconnects, where each second via interconnect comprises a partial ring planar cross section.

6. The package of claim 5, wherein the plurality of first via interconnects and the plurality of second via interconnects are located along at least one edge of the package.

7. The package of claim 5, wherein the plurality of second via interconnects are configured as an electromagnetic interference shield.

8. The package of claim 1, wherein the substrate comprises:
a core layer; and
a plug dielectric layer located laterally to the core layer,
wherein the first via interconnect extends through the core layer,
wherein the second via interconnect extends through the core layer,
wherein the plug dielectric layer includes a different material from the core layer, and
wherein the plug dielectric layer is located laterally between the first via interconnect and the second via interconnect.

9. The package of claim 8,
wherein the substrate further comprises a second plug dielectric layer coupled to the first via interconnect,
wherein the second plug dielectric layer is located on a side surface of the substrate, and
wherein the second plug dielectric layer is located at least laterally to the core layer.

10. A substrate comprising:
at least one dielectric layer; and
a plurality of interconnects comprising:
a first via interconnect comprising a partial concentric planar cross section; and
a second via interconnect comprising a partial ring planar cross section, wherein the second via interconnect laterally surrounds at least part of the first via interconnect.

11. The substrate of claim 10, further comprising:
a first pad interconnect coupled to the first via interconnect, wherein the first pad interconnect comprises a first partial concentric planar cross section;
a second pad interconnect coupled to the first via interconnect, wherein the second pad interconnect comprises a second partial concentric planar cross section;
a third pad interconnect coupled to the second via interconnect, wherein the third pad interconnect comprises a third partial concentric planar cross section; and
a fourth pad interconnect coupled to the second via interconnect, wherein the fourth pad interconnect comprises a fourth partial concentric planar cross section.

12. The substrate of claim 10, wherein the plurality of interconnects comprises:
a plurality of first via interconnects, where each first via interconnect comprises a partial concentric planar cross section; and
a plurality of second via interconnects, where each second via interconnect comprises a partial ring planar cross section.

13. The substrate of claim 12, wherein the plurality of first via interconnects and the plurality of second via interconnects are located along at least one edge of the substrate.

14. The substrate of claim 10, wherein the substrate comprises:
a core layer; and
a plug dielectric layer located laterally to the core layer,
wherein the at least one dielectric layer comprises:
a first dielectric layer coupled to a first surface of the core layer; and
a second dielectric layer coupled to a second surface of the core layer,
wherein the first via interconnect extends through the core layer, the first dielectric layer and the second dielectric layer,
wherein the second via interconnect extends through the core layer,
wherein the plug dielectric layer includes a different material from the core layer, and
wherein the plug dielectric layer is located laterally between the first via interconnect and the second via interconnect.

15. A package comprising:
a first substrate;
a first integrated device coupled to the first substrate;
a second substrate;
an encapsulation layer located between the first substrate and the second substrate, wherein the encapsulation layer is coupled to the first substrate and the second substrate; and
a plurality of package interconnects comprising:
a first package via interconnect comprising a partial concentric planar cross section; and
a second package via interconnect comprising a partial ring planar cross section, wherein the second via interconnect laterally surrounds at least part of the first via interconnect.

16. The package of claim 15, further comprising:
a first pad interconnect coupled to the first package via interconnect, wherein the first pad interconnect comprises a first partial concentric planar cross section;
a second pad interconnect coupled to the first package via interconnect, wherein the second pad interconnect comprises a second partial concentric planar cross section;
a third pad interconnect coupled to the second package via interconnect, wherein the third pad interconnect comprises a third partial concentric planar cross section; and
a fourth pad interconnect coupled to the second package via interconnect, wherein the fourth pad interconnect comprises a fourth partial concentric planar cross section.

17. The package of claim 16,
wherein the first pad interconnect and the third pad interconnect are interconnects of the first substrate, and
wherein the second pad interconnect and the fourth pad interconnect are interconnects of the second substrate.

18. The package of claim 15,
wherein the first package via interconnect extends through at least part of the first substrate, the encapsulation layer and the second substrate, and
wherein the second package via interconnect extends through at least part of the encapsulation layer.

19. The package of claim 15,
wherein the first package via interconnect is configured to provide a first electrical path for ground; and
wherein the second package via interconnect is configured to provide a second electrical path for power.

20. The package of claim 19, further comprising a second integrated device coupled to the second substrate, wherein power to the second integrated device travels through an electrical path that includes the second package via interconnect.
